(19) United States
(12) Patent Application Publication
(10) Pub. No.: US 2026/0059981 A1
(43) Pub. Date: Feb. 26, 2026

(54) DISPLAY DEVICE

(71) Applicant: LG Display Co., Ltd., Seoul (KR)

(72) Inventors: Intae KO, Paju-si (KR); Jinuk LEE, Paju-si (KR)

(73) Assignee: LG Display Co., Ltd., Seoul (KR)

(21) Appl. No.: 19/242,686

(22) Filed: Jun. 18, 2025

(30) Foreign Application Priority Data
Aug. 23, 2024 (KR) 10-2024-0113416

(51) Int. Cl. H10K 59/80; B60K 35/22; H10K 59/131

(52) U.S. Cl. CPC H10K 59/8731; B60K 35/22; H10K 59/131; H10K 59/879; B60K 2360/1523

(57) ABSTRACT

A display device can include a display panel having a notch portion and a display region and a non-display region around the display region, and a printed circuit film attached to the display panel. The display panel can include a substrate, at least one panel inorganic layer disposed on the substrate, a light emitting unit disposed on the at least one panel inorganic layer, and an encapsulation unit disposed on the light emitting unit. Further, the non-display region can include a notch non-display region disposed around the notch portion, and the encapsulation unit can be disposed up to an end portion of the notch non-display region.

### CROSS-REFERENCE TO RELATED APPLICATION

The present application claims priority to Korea Patent Application No. 10-2024-0113416, filed in the Republic of Korea on Aug. 23, 2024, the entire contents of which is hereby expressly incorporated by reference into the present application.

### BACKGROUND

### Field

The present disclosure relates to a display device.

### Discussion of the Related Art

With the progress of the information-oriented society, various types of demands for display devices which display an image are increasing. Further, various types of display devices such as a liquid crystal display (LCD) device, and an organic light emitting diode (OLED) display device have been used.

Among various display devices, the OLED display device of an emissive type device has advantages of a viewing angle and a contrast ratio as compared with the LCD device. Since an additional backlight unit is not required, the OLED display device has a light weight, a thin profile, and a low power consumption. In addition, the OLED display device is driven with a low voltage and has a fast response speed. Specifically, the OLED display device has a low fabrication cost.

The OLED display device can be applied to a display device mounted in a vehicle. Among the display devices mounted in the vehicle, a display device disposed in front of a driver seat and a front passenger seat may need to limit a viewing angle for the driver depending on a driving situation. The display device may need to limit the viewing angle for protection of privacy and information.

### SUMMARY OF THE DISCLOSURE

An object to be solved or addressed by aspects of the present disclosure is to provide a display device designed with an improved aesthetic.

Another object to be solved or addressed by aspects of the present disclosure is to provide a display device which can suppress or prevent defects of marks and scratches in the display device.

Still another object to be solved or addressed by aspects of the present disclosure is to provide a display device which can suppress or prevent defects of marks and scratches in the display device caused by a deposition mask.

Still another object to be solved or addressed by aspects of the present disclosure is to provide a display device with improved reliability by suppressing or preventing defects on the display panel.

Objects of the present disclosure are not limited to the above-described ones, and another technical problems can be inferred from a first embodiment of the present disclosure below.

One or more embodiments of the present disclosure can provide a display device, including a display panel having a notch portion and including a display region and a non-display region around the display region; and a printed circuit film attached to the display panel, and the display panel can include a substrate; at least one panel inorganic layer disposed on the substrate; a light emitting unit disposed on the at least one panel inorganic layer; and an encapsulation unit disposed on the light emitting unit, where the non-display region can include a notch non-display region disposed around the notch portion, and the encapsulation unit can be disposed up to an end of the notch non-display region.

Another embodiment of the present disclosure can provide a display device, including a substrate including a display region having a plurality of sub-pixels and a non-display region around the display region; at least one panel inorganic layer disposed on the substrate; a light emitting unit disposed on the at least one panel inorganic layer; an encapsulation unit disposed on the light emitting unit; a display panel including a touch unit disposed on the encapsulation unit; and a microlens disposed on a light emitting region of the sub-pixels, where the encapsulation unit can extend up to an end of the non-display region.

Details of embodiments of the present disclosure are included in the detailed description and the accompanying drawings.

According to embodiments of the present disclosure, it is possible to provide a display device with improved aesthetic.

According to embodiments of the present disclosure, it is possible to provide a display device which can suppress or prevent defects of marks and scratches in the display device.

According to embodiments of the present disclosure, it is possible to provide a display device which can suppress or prevent defects of marks and scratches in the display device caused by a deposition mask.

According to embodiments of the present disclosure, it is possible to provide a display device with improved reliability by suppressing or preventing defects on the display panel.

According to embodiments of the present disclosure, it is possible to prevent defects of the display device, and to improve life-span of the display device, thereby reducing production energy, because defects of marks and scratches in the display device can be suppressed or prevented.

The effects of the present disclosure are not limited to the above-described effects and other effects which are not described herein can be derived by those skilled in the art from the following description of the embodiments of the present disclosure.

### BRIEF DESCRIPTION OF THE DRAWINGS

The present disclosure will become more fully understood from the detailed description given hereinbelow and the accompanying drawings which are given by way of illustration only, and thus are not limitative of the present disclosure.

FIG. 1 is a plan view of a display device according to one or more embodiments of the present disclosure.

FIG. 2 is an enlarged view of Q1 region in FIG. 1.

FIG. 3 is a view only illustrating a display panel in FIG. 1.

FIG. 4 is a plan view illustrating pixel arrangement of a display device according to an embodiment of the present disclosure.

FIG. 5 is a cross-sectional view taken along V-V′ line in FIG. 4.

FIG. 6 is a cross-sectional view taken at a different angle from an angle of FIG. 5.

FIG. 7 is a plan view of a display panel according to an embodiment of the present disclosure.

FIG. 8 is a cross-sectional view taken along VIII-VIII′ line in FIG. 7.

FIG. 9 is a cross-sectional view taken along A-A′ line in FIG. 1.

FIG. 10 is a cross-sectional view taken along B-B′ line in FIG. 3.

FIG. 11 is a cross-sectional view taken along C-C′ line in FIG. 3.

FIG. 12 is a schematic view illustrating one step of a method for manufacturing a display device according to an embodiment of the present disclosure.

FIG. 13 is a plan view of a display device according to another embodiment of the present disclosure.

FIG. 14 is an enlarged view of Q2 region in FIG. 13.

FIG. 15 is a cross-sectional view taken along D-D′ line in FIG. 14.

FIG. 16 is a cross-sectional view of a display device according to another embodiment of the present disclosure.

### DETAILED DESCRIPTION OF THE EMBODIMENTS

Hereinafter, various embodiments of the disclosure will be described with reference to the drawings. In this specification, when it is mentioned that a component (or, an area, a layer, a part, etc.) is referred to as being “on”, “connected to” or “combined to” another component, this means that the component can be directly on, connected to, or combined to the other component or a third component therebetween can be present.

Like reference numerals refer to like elements. Additionally, in the drawings, the thicknesses, proportions, and dimensions of components are exaggerated for effective description. “And/or” includes all of one or more combinations defined by related components.

It will be understood that the terms “first” and “second” are used herein to describe various components but these components should not be limited by these terms. The above terms are used only to distinguish one component from another and may not define order or sequence. For example, a first component can be referred to as a second component and vice versa without departing from the scope of the disclosure. The singular expressions include plural expressions unless the context clearly dictates otherwise.

In addition, terms such as “below”, “the lower side”, “on”, and “the upper side” are used to describe a relationship of configurations shown in the drawing. The terms are described as a relative concept based on a direction shown in the drawings.

In various embodiments of the disclosure, the term “include,” “comprise,” “including,” or “comprising,” specifies a property, a fixed number, a step, a process, an element and/or a component, or a combination thereof, but does not exclude presence or addition of other properties, fixed numbers, steps, processes, elements and/or components, or a combination thereof. Further, the term “can” encompasses all the meanings and coverages of the term “may” and vice versa.

Features of various embodiments of the present disclosure can be partially or entirely coupled to or combined with each other and can be operated, linked, or driven together in various ways. Embodiments of the present disclosure can be carried out independently from each other, or can be carried out together in co-dependent or related relationship.

Now, various embodiments of the present disclosure will be discussed referring to the drawings. All the components of each display device or apparatus according to all embodiments of the present disclosure are operatively coupled and configured.

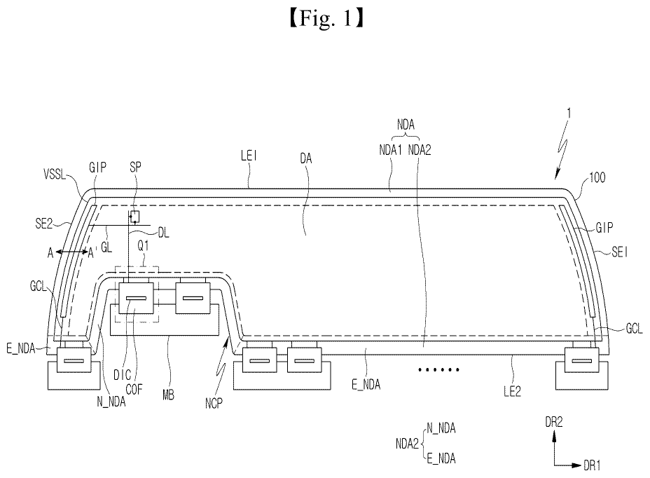

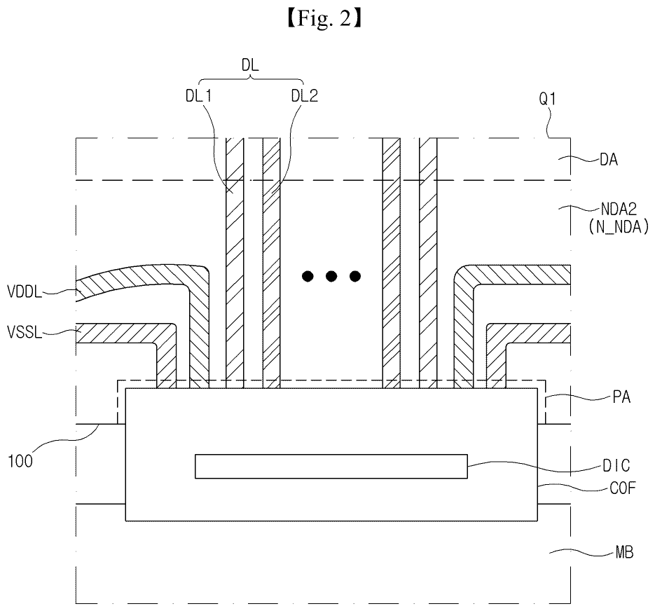

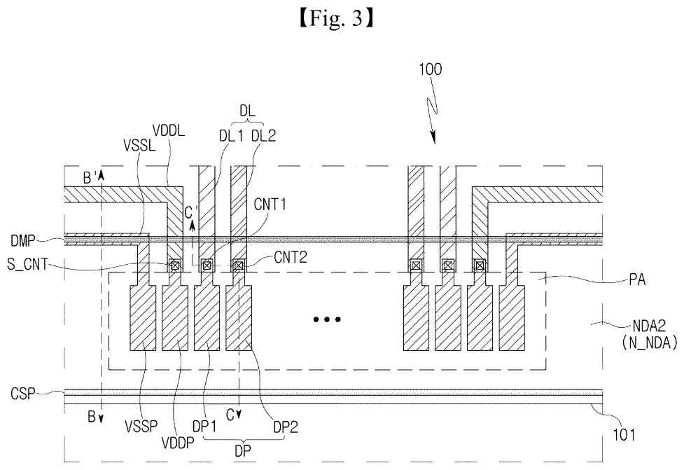

FIG. 1 is a plan view of a display device according to one or more embodiments of the present disclosure. FIG. 2 is an enlarged view of Q1 region in FIG. 1. FIG. 3 is a view only illustrating a display panel in FIG. 1. More specifically, FIG. 3 is a view in which a flexible film COF, a main substrate MB, and a driver IC DIC are omitted from a view of FIG. 2 except the display panel 100. In FIG. 3, for convenience of description, percentages between components are adjusted.

Referring to FIGS. 1 to 3, a display device 1 can be a device which includes both a display function displaying an image and a touch sensing function sensing a touch of the user, but is not limited thereto. For example, the display device 1 can include one among a display function displaying an image and a touch sensing function sensing a touch of the user.

The display device 1 can be a micro light emitting diode device or an electroluminescent display device, which includes a touch sensor. The electroluminescent display device which includes a touch sensor can be an organic light emitting diode device (OLED), a quantum-dot light emitting diode display device, or an inorganic light emitting diode device.

The display device 1 according to the present embodiment can be a display device for a vehicle, but is not limited thereto. For example, description on the display device 1 can be applied without limitation to kinds of devices, only if a display function is included thereto.

When the display device 1 according to the present embodiment is a display device for a vehicle, the display device 1 can include a function of manipulating at least some of various functions of a vehicle, and a function representing various information related to the vehicle, and the like.

When the display device 1 according to the present embodiment is a display device for a vehicle, the display device 1 can be disposed in a dashboard of the vehicle. The display device 1 can be disposed to traverse a driver seat and a front passenger seat disposed on a front side of the vehicle, but is not limited thereto. The driver sat on the driver seat and the passenger sat on the front passenger seat both can use the display device 1.

The display device 1 can use a display panel 100. The display panel 100 can include a display region DA and a non-display region DNA.

The display region DA can be a region in which a screen can be displayed as light is emitted to the outside. The display region DA can further include a function for sensing a touch of the user. In such a case, the display region DA can correspond to a touch sensing region, but is not limited thereto.

The display region DA can correspond to a shape of the display panel 100, but is not limited thereto.

A plurality of sub-pixels SP (or pixel) can be disposed in the display region DA. The plurality of sub-pixels SP (or pixel) can be disposed repeatedly along a first direction DR1 and a second direction DR2.

The non-display region NDA can be a region in which the screen is not displayed because light is not emitted to the outside. The non-display region NDA can be disposed around the display region DA. The non-display region NDA can surround the display region DA, but embodiments of the present disclosure are not limited thereto. A bezel region of the display device 1 can be defined by the non-display region NDA, but embodiments of the present disclosure are not limited thereto.

The display panel 100 can be a rigid display panel, but embodiments of the present disclosure are not limited thereto. The display panel 100 can be a flexible display panel of which the shape can be deformed, such as a foldable display panel, a bendable display panel, a rollable display panel, and a stretchable display panel.

The display panel 100 can include a first long side LE1, a second long side LE2, a first short side SE1, and a second short side SE2 configuring an edge of the display panel 100.

The first long side LE1 and the second long side LE2 extend in the first direction DR1, and the first short side SE1 and the second short side SE2 extend in a direction between the first direction DR1 and the second direction DR2. The first long side LE1 and the second long side LE2 can be connected to each other at both ends through the first short side SE1, and the second short side SE2.

The first long side LE1 can be disposed on one side of the second long side LE2. The first long side LE1 and the second long side LE2 can extend in parallel to each other, but are not limited thereto.

A length of the first long side LE1 can be shorter than a length of the second long side LE2. Therefore, the first short side SE1 and the second short side SE2 can extend in a direction intersecting each other, but are not limited thereto.

The first direction DR1 and the second direction DR2 can be directions intersecting each other. The first direction DR1 and the second direction DR2 can be orthogonal to each other, but are not limited thereto. The first direction DR1 and the second direction DR2 are provided for facilitating description of the present disclosure to be more accurate, and the first direction DR1 and the second direction DR2 are relative to each other, but embodiments of the present disclosure are not limited thereto.

When viewed in a plan view, the first long side LE1 is disposed on the display region DA, and the second long side LE2 can be disposed below the display region DA.

When viewed in a plan view, the first short side SE1 can be disposed on a right side of the display region DA, and the second short side SE2 can be disposed on a left side of the display region DA1.

The display panel 100 can include a curved notch portion NCP. The notch portion NCP can be formed in the second long side LE2, but is not limited thereto. In other words, the second long side LE2 in its entirety extends along the first direction DR1, but can include the notch portion NCP curved toward the first long side LE1.

As the notch portion NCP is disposed, parts such as a handle of the driver seat can be disposed in the notch portion NCP, and the display region DA which can be displayed can be maximized, thereby the user convenience and the aesthetic can be improved.

The non-display region NDA can include a first non-display region NDA1 disposed along the first long side LE1, the first short side SE1, and the second short side SE2, and a second non-display region NDA2 disposed along the second long side LE2. The second non-display region NDA2 can be disposed along the second long side LE2 which includes the curved notch portion NCP.

The first non-display region NDA1 is disposed on one side and the other side of the first direction DR1 in the display region DA, and therefore, can be disposed on one side of the second direction DR2 in the display region DA.

The second non-display region NDA2 can include a notch non-display region N_NDA disposed around the notch portion NCP, and an extending non-display region E_NDA disposed around the notch non-display region N_NDA.

The extending non-display region E_NDA can extend along the first direction DR1 from the notch non-display region N_NDA. The extending non-display region E_NDA can be disposed between the notch non-display region N_NDA and the first non-display region NDA1. The extending non-display region E_NDA can connect the notch non-display region N_NDA and the first non-display region NDA1 to each other.

The display device 1 can further include a pad region PA, a gate driver GIP, a main substrate MB, a flexible film COF, a driver IC DIC, a gate control line GCL, a data line DL, a low potential voltage line VSSL, and a high potential voltage line VDDL.

The pad region PA can overlap the flexible film COF. The pad region PA can be attached to the flexible film COF. In other words, through the pad region PA, the display panel 100 and the flexible film COF can be attached to each other.

The pad region PA can be disposed in the non-display region NDA. The pad region PA can be disposed in the second non-display region NDA2. The pad region PA can be disposed in each of the notch non-display region N_NDA and the extending non-display region E_NDA.

The pad region PA can include a plurality of pads. The pad region PA can include a low potential voltage pad VSSP, a high potential voltage pad VDDP, a first data pad DP1 and a second data pad PD2. In the pad region PA, the low potential voltage pad VSSP, the high potential voltage pad VDDP, the first data pad DP1, and the second data pad PD2 can be disposed.

In FIG. 3, it is illustrated that the low potential voltage pad VSSP, the high potential voltage pad VDDP, the first data pad DP1, and the second data pad PD2 are sequentially disposed, however the embodiment is not limited thereto. For example, the first data pad DP1 and the second data pad DP2 can be disposed between the low potential voltage pad VSSP and the high potential voltage pad VDDP.

However, the embodiment is not limited thereto, and the pad region PA, disposed in a region overlapping the flexible film COF disposed at both ends among the flexible film COF disposed along the non-display region NDA, can further include a gate control pad.

The gate driver GIP can be disposed in the non-display region NDA. The gate driver GIP can be disposed on one among onside and the other side in a first direction DR1, however, it is not limited thereto. When viewed in a plan view, the gate driver GIP can be disposed on a left side or the other side of the display region DA.

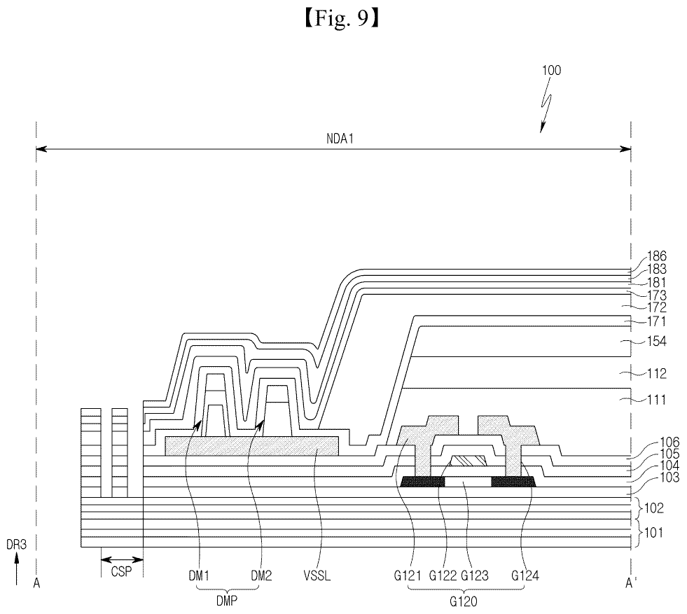

The gate driver GIP can include a plurality of transistors (refer to G120 in FIG. 9). The transistors (refer to G120 in FIG. 9) disposed in the gate driver GIP can be connected to the sub-pixel SP (or a pixel) through a gate line GL. The gate driver GIP can apply a gate signal to each sub-pixel SP (or a pixel) through the gate line GL.

The gate driver GIP can be applied with a gate control signal through the gate control line GCL from a driver IC DIC. The gate driver GIP can generate a scan signal and a light emission signal (or a light emission control signal) based on the gate control signal. The gate driver GIP can include a scan driver and a light emission signal driver. The scan driver can generate a scan signal in a row sequential manner and supply the scan signal to scan lines so as to drive at least one or more scan lines connected to each row. The emission signal driver can generate a light emission signal in a row sequential manner and supply the light emission signal to light emission signal lines so as to drive at least one or more light emission signal line connected to each row.

The main substrate MB can be connected to the display panel 100 through the flexible film COF. The main substrate MB can be electrically connected to a sub-pixel SP (or a pixel) in the display region DA through the flexible film COF. The main substrate MB can be electrically connected to the flexible film COF. The main substrate MB and the flexible film COF can be electrically connected to each other through a plurality of pads VSSP, VDDP and DP.

On the main substrate MB, various parts for supplying various signals such as the gate control signal, a driving signal, a data signal, and the like to the driver IC DIC can be disposed. The main substrate MB can be a printed circuit board, but is not limited thereto.

The main substrate MB can be connected to the display panel 100 through the flexible film COF in the second non-display region NDA2. The main substrate MB can be provided in plural number along the second non-display region NDA2, but is not limited thereto. The quantity of the main substrate MB can be changed variously according to the design.

One among the main substrate MB can be disposed around the notch portion NCP, and can be connected to the display panel 100 through the flexible film COF in the notch non-display region N_NDA.

The flexible film COF can be connected to the display panel 100 and the main substrate MB. The flexible film COF can be attached to each of the display panel 100 and the main substrate MB, and can be electrically connected to each of the display panel 100 and the main substrate MB. In other words, the display panel 100 and the main substrate MB can be electrically connected to each other through the flexible film COF. The flexible film COF can be provided in plural number, but the quantity thereof is not limited thereto.

The flexible film COF can be attached to the display panel 100 in the second non-display region NDA2. The flexible film COF can be disposed repeatedly along the second non-display region NDA2. The flexible film COM can be attached to the display panel 100 across the notch non-display region N_NDA and the extending non-display region E_NDA.

One main substrate MB can be electrically connected to the display panel 100 through at least one flexible film COF. For example, the main substrates MB disposed at both ends among the plurality of main substrates MB disposed along the second non-display region NDA2 can be electrically connected to the display panel 100 through one flexible film COF, and each of the remaining main substrates MB can be electrically connected to the display panel 100 through two flexible films COF.

The flexible film COF can be electrically connected to the pad region PA. By doing so, the flexible film COF can supply the gate control signal, a driving signal, a power supply voltage, a data voltage, and the like to the plurality of sub-pixels SP (or pixels) disposed in the display region DA and the gate driver GIP.

The flexible film COF can be a flexible insulation film including a plurality of conductive wirings. The fixable film COF can include, for example, polycarbonate, polyethylene terephthalate, polyimide, polyamide, polyester, polyacrylate, polymethyl methacrylate and the like, but is not limited thereto.

The driver IC DIC can be mounted on the flexible film COF. The driver IC DIC can be disposed in manners such as Chip-on-glass, Chip-on-film, Tape-carrier-package, and the like according to a manner of mounting. In the prevent disclosure, the driver IC DIC is described to be mounted on the flexible film COF in the Chip-on-film manner, but is not limited thereto.

The driver IC DIC can drive the display device 1. The driver IC DIC can process a data signal for displaying an image and various driving signals for processing the data signal. The driver IC DIC can include a gate driver IC, a data driver IC, and the like.

Although not illustrated, the display device 1 can further include a low dropout (LDO) regulator, and a level shifter. The low dropout (LDO) regulator and the level shifter can be disposed on the main substrate MB, but are not limited thereto.

The driver IC DIC can be electrically connected to the low dropout (LDO) regulator and the level shifter, and can deliver a signal generated in the dropout (LDO) regulator and the level shifter to the gate driver GIP.

The gate line GL can extend from the gate driver GIP, and can be connected to the sub-pixel SP (or a pixel). The gate line GL can electrically connect the gate driver GIP and the sub-pixel SP (or a pixel) to each other. The gate line GL can apply a gate signal to each sub-pixel SP (or a pixel) from the gate driver GIP.

The gate control line GCL can be disposed in the non-display region NDA. The gate control line GCL can extend from the pad region PA to the gate driver GIP, and can be electrically connected to the gate driver GIP.

The gate control line GCL can be provided in plural number, and the plurality of gate control lines GCL can supply at least two different signals.

The gate control line GCL can apply the gate control signal to the gate driver GIP. The gate control signal can be delivered from the main substrate MB or the driver IC DIC. The gate control line GCL can electrically connect the gate driver GIP to the main substrate MB or the driver IC DIC.

The gate control line GCL can be electrically connected to the flexible films COF disposed at both ends among the plurality of flexible films COF connected to the display panel 100 along the second non-display region NDA2. The gate control line GCL can be disposed at an outermost position among a plurality of lines connected to one flexible film COF, but is not limited thereto.

The data line DL can extend from the pad region PA, and can be connected to the sub-pixel SP (or a pixel) in the display region DA. The data line DL can apply a data signal to each sub-pixel SP (or a pixel). The data signal can be applied from the main substrate MB or the driver IC DIC. The data line DL can electrically connect the sub-pixel SP (or a pixel) to the main substrate MB or the driver IC DIC.

The data line DL can include a first data line DL1 and a second data line DL2. The data line DL can be connected to data pads DP1 and DP2. The first data line DL1 can contact the first data pad DP1 through a first data contact hole CNT1 to be electrically connected to the first data pad DP1. The second data line DL2 can contact the second data pad DP2 through a second data contact hole CNT2 to be electrically connected to the second data pad DP2.

The low potential voltage line VSSL can be disposed in the non-display region NDA in a manner of surrounding the display region DA. The low potential voltage line VSSL can be disposed in the non-display region NDA with the display region DA and the gate driver GIP interposed between the non-display regions NDA. In other words, the gate driver GIP can be disposed between the display region DA and the low potential voltage line VSSL.

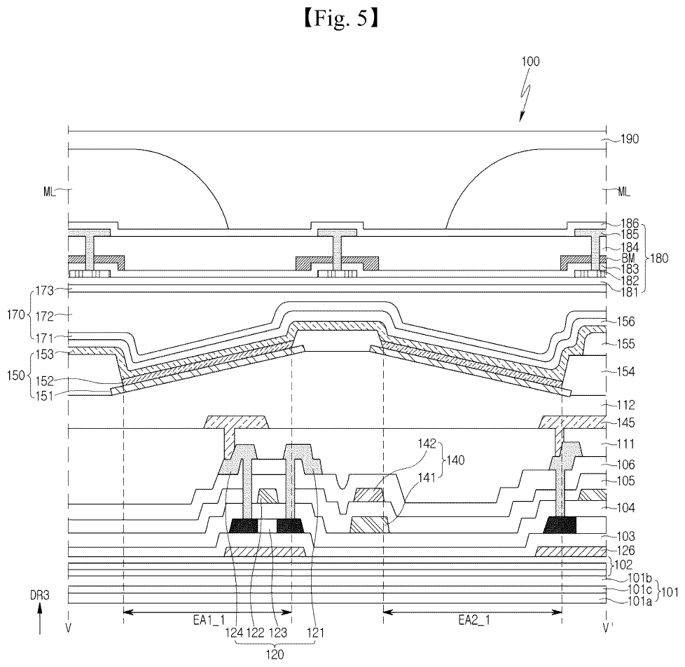

The low potential voltage line VSSL can apply a low potential voltage to the sub-pixel SP (or a pixel). The low potential voltage line VSSL is electrically connected to a cathode electrode (refer to 153 in FIG. 5) of the sub-pixel SP (or a pixel), and can apply the low potential voltage.

The low potential voltage line VSSL can be connected to the pad region PA. The low potential voltage line VSSL can be physically connected to the low potential voltage pad VSSP, and can be electrically connected to the low potential voltage pad VSSP. The low potential voltage line VSSL and the low potential voltage pad VSSP can be integrally formed, but are not limited thereto.

The high potential voltage line VDDL can be disposed between the display region DA and the low potential voltage line VSSL in the non-display region NDA. The high potential voltage line VDDL can further include a high potential connection electrode. The high potential connection electrode can be disposed in a different layer from a layer on which the high potential voltage line VDDL is disposed. For example, the high potential connection electrode can be disposed between a second insulation layer 104 and a third insulation layer 105. The high potential connection electrode can electrically connect the high potential voltage line VDDL and an anode electrode (refer to 151 in FIG. 5) across wirings disposed on the same layer as a layer of the high potential voltage line VDDL. The high potential connection electrode can be electrically connected to the anode electrode (refer to 151 in FIG. 5) across wirings disposed on the same layer as the layer of the high potential voltage line VDDL.

The high potential voltage line VDDL can apply the high potential voltage to the sub-pixel SP (or a pixel). The high potential voltage line VDDL is electrically connected to the anode electrode (refer to 151 in FIG. 5), and can apply the high potential voltage.

The high potential voltage line VDDL can be connected to the pad region PA. The high potential voltage line VDDL can be physically connected to the high potential voltage pad VDDP, and can be electrically connected to the high potential voltage pad VDDP. The high potential voltage line VDDL and the high potential voltage pad VDDP can contact each other through a contact hole S_CNT.

However, the embodiment is not limited thereto, and the high potential voltage line VDDL can be disposed on the same layer as a layer of the high potential voltage pad VDDP to be formed integrally. For example, the high potential voltage line VDDL can include the same material as a material of the high potential voltage pad VDDP, and formed of the same conductive layer as a conductive layer of the high potential voltage pad VDDP, and can be formed together through the same mask process.

In such cases, the high potential connection electrode which is disposed on a different layer from the layer of the high potential voltage pad VDDP can be further included. The high potential connection electrode can electrically connect the high potential voltage line VDDL and the anode electrode (refer to 151 in FIG. 5) across wirings disposed on the same layer as the layer of the high potential voltage line VDDL.

The display device 1 can further include a dam portion DMP. The dam portion DMP can be disposed in the non-display region NDA. The dam portion DMP can be disposed to surround the display region DA, but is not limited thereto. The dam portion DMP can be disposed such that at least some thereof overlaps the low potential voltage line VSSL. The dam portion DMP can be disposed between the display region DA and the pad region PA in the second non-display region NDA.

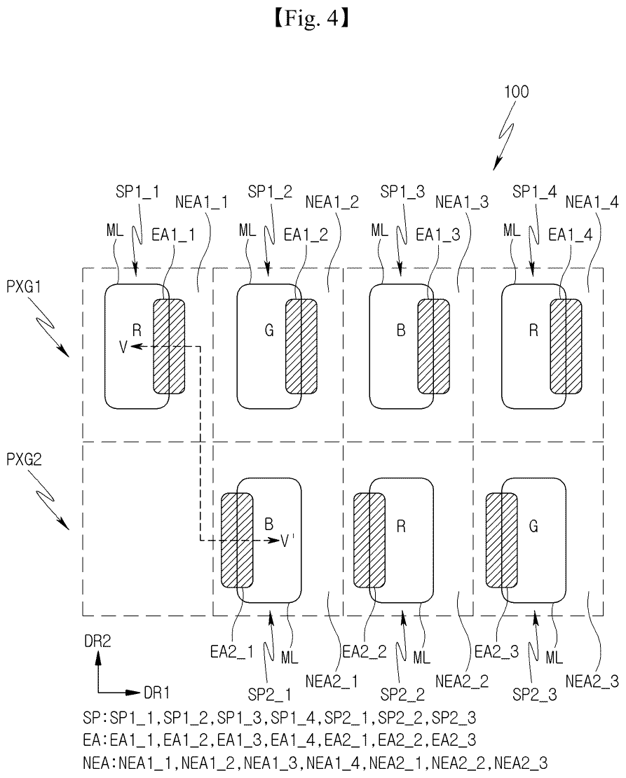

FIG. 4 is a plan view illustrating pixel arrangement of the display device according to an embodiment of the present disclosure. The plan view of FIG. 4 shows a portion of the display region DA, in which the pixel PX is disposed, in an enlarged form.

Referring to FIG. 4, the display panel 100 can include a first pixel group PXG1 and a second pixel group PXG2.

Each of the first pixel group PXG1 and the second pixel group PXG2 can be repeatedly disposed along the first direction DR1. The first pixel group PXG1 and the second pixel group PXG2 can be alternately and repeatedly disposed along the second direction DR2.

The sub-pixel SP can include a (1_1)th sub-pixel SP1_1, a (1_2)th sub-pixel SP1_2, a (1_3)th sub-pixel SP1_3, a (1_4)th sub-pixel SP1_4, a (2_1)th sub-pixel SP2_1, a (2_2)th sub-pixel SP2_2, and a (2_3)th sub-pixel SP2_3.

A first pixel group PXG1 can include a (1_1)th sub-pixel SP1_1, a (1_2)th sub-pixel SP1_2, a (1_3)th sub-pixel SP1_3, and a (1_4)th sub-pixel SP1_4. The (1_1)th sub-pixel SP1_1, (1_2)th sub-pixel SP1_2, (1_3)th sub-pixel SP1_3, and (1_4)th sub-pixel SP1_4 are disposed in parallel along the first direction.

The (1_1)th sub-pixel SP1_1 can emit a red R light, the (1_2)th sub-pixel SP1_2 can emit a green G light, the (1_3)th sub-pixel SP1_3 can emit a blue B light, and the (1_4)th sub-pixel SP1_4 can emit a red R light.

Each of the (1_1)th sub-pixel SP1_1, the (1_2)th sub-pixel SP1_2, the (1_3)th sub-pixel SP1_3, and the (1_4)th sub-pixel SP1_4 can include an emitting region EA1_1, EA1_2, EA1_3 and EA1_4, and a non-emitting region NEA1_1, NEA1_2, NEA1_3 and NEA1_4 disposed around the light emitting regions EA1_1, EA1_2, EA1_3 and EA1_4.

The (1_1)th sub-pixel SP1_1 can include a (1_1)th emitting region EA1_1 and a (1_1)th non-emitting region NEA1_1 disposed around the (1_1)th emitting region EA1_1.

The (1_2)th sub-pixel SP1_2 can include a (1_2)th emitting region EA1_2 and a (1_2)th non-emitting region NEA1_2 disposed around the (1_2)th emitting region EA1_2.

The (1_3)th sub-pixel SP1_3 can include a (1_3)th emitting region EA1_3 and a (1_3)th non-emitting region NEA1_3 disposed around the (1_3)th emitting region EA1_3.

The (1_4)th sub-pixel SP1_4 can include a (1_4)th emitting region EA1_4 and a (1_4)th non-emitting region NEA1_4 disposed around the 1_4 emitting region EA1_1.

The second pixel group PXG2 can include a (2_1)th sub-pixel SP2_1, a (2_2)th sub-pixel SP2_2, and a (2_3)th sub-pixel SP2_3. The (2_1)th sub-pixel SP2_1, the (2_2)th sub-pixel SP2_2, and the (2_3)th sub-pixel SP2_3 can be disposed in parallel along the second direction.

The (2_1)th sub-pixel SP2_1 can emit a blue B light, the (2_2)th sub-pixel SP2_2 can emit a red R light, and the (2_3)th sub-pixel SP2_3 can emit a green G light.

Each of the (2_1)th sub-pixel SP2_1, the (2_2)th sub-pixel SP2_2, and the (2_3)th sub-pixel SP2_3 can include an emitting region EA2_1, EA2_2 and EA2_3 and a non-emitting region NEA2_1, NEA2_2 and NEA2_3 disposed around the emitting regions EA2_1, EA2_2 and EA2_3.

The (2_1)th sub-pixel SP2_1 can include a (2_1)th emitting region EA2_1, and a (2_1)th non-emitting regionNEA2_1 disposed around the (2_1)th emitting region EA2_1.

The (2_2)th sub-pixel SP2_2 can include a (2_2)th emitting regionEA2_2, and a (2_2)th non-emitting regionNEA2_2 disposed around the (2_2)th emitting regionEA2_2.

The (2_3)th sub-pixel SP2_1 can include a (2_3)th emitting regionEA2_3, and a (2_3)th non-emitting regionNEA2_3 disposed around the (2_3)th emitting regionEA2_3.

When viewed in a plan view, the sub-pixel may not be disposed below the (1_1)th sub-pixel SP1_1 (the other side in the second direction DR2).

When viewed in a plan view, the (2_1)th sub-pixel SP2_1 can be disposed below (the other side in the second direction DR2) the (1_2)th sub-pixel SP1_2.

When viewed in a plan view, the (2_2)th sub-pixel SP2_2 can be disposed below (the other side in the second direction DR2) the (1_3)th sub-pixel SP1_3.

When viewed in a plan view, the (2_3)th sub-pixel SP2_3 can be disposed below (the other side in the second direction DR2) the (1_4)th sub-pixel SP1_4.

The sub-pixel illustrated in FIG. 1 (refer to SP in FIG. 1) can refer to one among the (1_1)th sub-pixel SP1_1, the (1_2)th sub-pixel SP1_2, the (1_3)th sub-pixel SP1_3, the (1_4)th sub-pixel SP1_4, the (2_1)th sub-pixel SP2_1, the (2_2)th sub-pixel SP2_2, and the (2_3)th sub-pixel SP2_3.

A microlens ML can be disposed on the (1_1)th sub-pixel SP1_1, the (1_2)th sub-pixel SP1_2, the (1_3)th sub-pixel SP1_3, the (1_4)th sub-pixel SP1_4, the (2_1)th sub-pixel SP2_1, the (2_2)th sub-pixel SP2_2, and the (2_3)th sub-pixel SP2_3. The microlens ML can be disposed on each of the sub-pixels SP (SP1_1, SP1_2, SP1_3, SP1_4, SP2_1, SP2_2, SP2_3).

It is illustrated that one microlens ML is disposed on each of the sub-pixels SP, but is not limited thereto. For example, according to a design of each sub-pixel SP, the microlens ML disposed on each of the sub-pixels SP can be provided in plural number which is two or more. When an opening (the emitting region EA) configured in one sub-pixel SP is in plural number, the microlens ML can be disposed in each opening, or a plurality of microlenses ML can be disposed in one opening.

Each sub-pixel SP (SP1_1, SP1_2, SP1_3, SP1_4, SP2_1, SP2_2, SP2_3) can include the emitting region (EA1_1, EA1_2, EA1_3, EA1_4, EA2_1, EA2_2, EA2_3) and the non-emitting region NEA (NEA1_1, NEA1_2, NEA1_3, NEA1_4, NEA2_1, NEA2_2, NEA2_3) disposed around the emitting region EA.

Hereinafter, referring to FIG. 5, a cross-sectional structure of the display region DA of the display panel 100 which includes the sub-pixels SP (SP1_1, SP1_2, SP1_3, SP1_4, SP2_1, SP2_2, SP2_3) will be described.

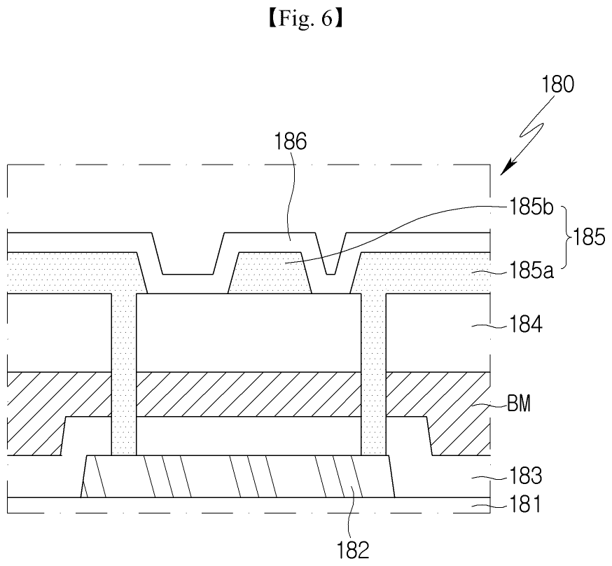

FIG. 5 is a cross-sectional view taken along V-V′ line in FIG. 4. FIG. 6 is a cross-sectional view taken at a different angle from an angle of FIG. 5.

Referring to FIGS. 4 to 6, the display panel 100 can include a substrate 101, a thin film transistor 120, a storage electrode 140, a light emitting unit 150, an encapsulation unit 170, and a touch unit 180. However, the embodiments of the present disclosure are not limited thereto.

The substrate 101 can provide a space in which various components can be disposed on an upper portion thereof. The substrate 101 can correspond to a plane shape of the display panel 100. In other words, the substrate 101 can include the notch portion NCP. The substrate 101 can include the display region DA and the non-display region NDA of the display panel 100 substantially equally.

The substrate 101 can include one or more plastic materials, but is not limited thereto, and can include a glass material.

The substrate 101 can be a multi-substrate which includes a plurality of substrates such as a first substrate 101a, a second substrate 101b, and a third substrate 103c, each of which includes a plastic material such as polyimide and the like, but the embodiments of the present disclosure are not limited thereto. For example, the substrate 101 can be a single substrate consisting of one layer.

The substrate 101 can include a rigid substrate. However, the substrate 101 is not limited thereto, and the substrate 101 can include a flexible substrate.

A buffer layer 102 can be disposed on the substrate 101. The buffer layer 102 can minimize or delay dispersion of moisture or oxygen permeating the substrate 101. The buffer layer 102 can be formed by depositing silicon oxide SiOx or silicon nitride SiNx alternately at least once, and the embodiments of the present disclosure are not limited thereto.

In the present disclosure, it is illustrated that the buffer layer 102 is formed as a multi-layer consisting of three layers, however, the quantity of layers forming the buffer layer 102 is not limited thereto, and the buffer layer 102 can be formed as a single layer.

On the buffer layer 102, a first light shielding layer 126 can be disposed. The first light shielding layer 126 can prevent light transmission through a semiconductor layer 123 of the thin film transistor 120. For example, the semiconductor layer 123 can be disposed to overlap the first light shielding layer 126. The first light shielding layer 126 can be formed in a single-layered structure or a multi-layered structure formed of one among molybdenum (Mo), aluminum (Al), chrome (Cr), nickel (Ni), neodymium (Nd), and copper (Cu), or an alloy thereof, but the embodiments of the present disclosure are not limited thereto.

A first insulation layer 103 can be disposed on the first light shielding layer 126. The first insulation layer 103 can prevent an electrical short between components of the thin film transistor 120 and the first light shielding layer 126. The first insulation layer 103 can be formed of the same material as a material of the buffer layer 102, however the embodiments of the present disclosure are not limited thereto. For example, the first insulation layer 103 can be formed of an inorganic material such as silicon oxide SiOx or silicon nitride SiNx, however the embodiments of the present disclosure are not limited thereto.

The thin film transistor 120 can be disposed on the first insulation layer 103. The thin film transistor 120 can include a source electrode 121, a gate electrode 122, the semiconductor layer 123, and a drain electrode 124.

The semiconductor layer 123 can be disposed on the first insulation layer 103. The semiconductor layer 123 can include a metal oxide semiconductor such IGZO (Indium-Gallium-Zinc Oxide), or a silicon-based semiconductor material such as amorphous silicon or polycrystalline silicon, however the embodiments of the present disclosure are not limited thereto. The semiconductor layer 123 can include a source region, a drain region, and a channel region between the source region and the drain region.

A polycrystalline semiconductor layer can have better mobility than an amorphous semiconductor and an oxide semiconductor layer, consume less power and have excellent reliability. Thus, the driving transistor can be formed of the polycrystalline semiconductor layer, however the embodiments of the present disclosure are not limited thereto.

A second insulation layer 104 can be disposed on the semiconductor layer 123. The second insulation layer 104 can be formed of the same material as a material of the first insulation layer 103, however the embodiments of the present disclosure are not limited thereto. The second insulation layer 104 can prevent an electrical short between the other component of the thin film transistor 120 and the semiconductor layer 123.

The gate electrode 122 can be disposed on the second insulation layer 104. The gate electrode 122 can be disposed on the second insulation layer 104 to overlap the channel region of the semiconductor layer 123. The gate electrode 122 can be formed in a single-layered structure or a multi-layered structure formed of one among molybdenum (Mo), copper (Cu), titanium (Ti), aluminum (Al), chrome (Cr), gold (Au), nickel (Ni), neodymium (Nd), and or an alloy thereof, but the embodiments of the present disclosure are not limited thereto. The gate electrode 122 can be disposed together with a gate line, but the embodiments of the present disclosure are not limited thereto.

A third insulation layer 105 can be disposed on the gate electrode 122. The third insulation layer 105 can be formed of the same material as a material of the first insulation layer 103 or the second insulation layer 104, but the embodiments of the present disclosure are not limited thereto.

A storage electrode 140 can be spaced apart from the thin film transistor 120. The storage electrode 140 can include a first storage electrode 141, and a second storage electrode 142.

The first storage electrode 141 can be formed of the same material as a material of the gate electrode 122 and disposed on the same layer as a layer of the gate electrode 122, but the embodiments of the present disclosure are not limited thereto.

On the first storage electrode 141, the second storage electrode 142 can be disposed. The second storage electrode 142 can be disposed on the third insulation layer 105, and a capacitance can be formed with the third insulation layer 105 between the first storage electrode 141 and the second storage electrode 142 serving as the dielectric. The second storage electrode 142 can be formed of the same material as a material of the first storage electrode 141, but the embodiments of the present disclosure are not limited thereto.

A fourth insulation layer 106 can be disposed on the second storage electrode 142. The fourth insulation layer 106 can be formed of the same material as a material of the first insulation layer 103, the second insulation layer 104, and the third insulation layer 105, but the embodiments of the present disclosure are not limited thereto.

The source electrode 121 and the drain electrode 124 can be disposed on the fourth insulation layer 106.

The source electrode 121 and the drain electrode 124 can be electrically connected to the semiconductor layer 123 through the contact hole. The source electrode 121 and the drain electrode 124 can be formed of a metal material. For example, the source electrode 121 and the drain electrode 124 can be formed in a single-layered structure or a multi-layered structure formed of one among molybdenum (Mo), aluminum (Al), chrome (Cr), gold (Au), titanium (Ti), nickel (Ni), neodymium (Nd), and copper (Cu), or an alloy thereof, but the embodiments of the present disclosure are not limited thereto.

The source electrode 121 and the drain electrode 124 can be disposed together with a data line. For example, the data line can be formed of the same material of a material of the source electrode 121 and the drain electrode 124, and can be formed on the same layer as a layer of the source electrode 121 and the drain electrode 124, but the embodiments of the present disclosure are not limited thereto.

The thin film transistor 120 can be a driving transistor, and though not illustrated, the display panel 100 can further include a switching transistor, but the embodiments of the present disclosure are not limited thereto.

A first protection layer 111 can be disposed on the source electrode 121 and the drain electrode 124.

The first protection layer 111 can planarize an upper portion of the thin film transistor 120, and protect the thin film transistor 120. The first protection layer 111 can be formed of an organic material. For example, the first protection layer 111 can be formed of an organic material including an acrylic resin, an epoxy resin, a phenolic resin, a polyamide resin, or a polyimide resin, but the embodiments of the present disclosure are not limited thereto.

A second protection layer 112 can be disposed on the first protection layer 111. The second protection layer 112 can be formed of the same material as a material of the first protection layer 111, but the embodiments of the present disclosure are not limited thereto.

A connection electrode 145 can be disposed between the first protection layer 111 and the second protection layer 112.

The connection electrode 145 can electrically connect the thin film transistor 120 and the light emitting unit 150. The connection electrode 145 can be formed of the same material as the material of the source electrode 121 and the drain electrode 124, but the embodiments of the present disclosure are not limited thereto.

The connection electrode 145 can be electrically connected to the drain electrode 124 by contacting the drain electrode 124 through a contact hole formed on the first protection layer 111.

The connection electrode 145 can be formed in a single-layered structure or a multi-layered structure formed of one among molybdenum (Mo), aluminum (Al), chrome (Cr), gold (Au), titanium (Ti), nickel (Ni), neodymium (Nd), and copper (Cu), or an alloy thereof, but the embodiments of the present disclosure are not limited thereto.

The light emitting unit 150 can be formed on the second protection layer 112. The light emitting unit 150 can include an anode electrode 151, an organic layer 152, and a cathode electrode 153.

The anode electrode 151 can be disposed on the second protection layer 112. The anode electrode 151 can be electrically connected to the thin film transistor 120 through the contact hole formed on the first protection layer 111 and the second protection layer 112.

The anode electrode 151 can be a reflective electrode which reflects light, but the embodiments of the present disclosure are not limited thereto. The anode electrode 151 can include a metal material having a high reflectance such as an APC alloy (Ag/Pd/Cu), a deposition structure (Ti/Al/Ti) of aluminum (Al) and titanium (Ti), and a deposition structure (ITO/Al/ITO) of aluminum (Al) and ITO, and can be formed in a single-layered structure or a multi-layered structure, but the embodiments of the present disclosure are not limited thereto.

The organic layer 152 can be disposed on the anode electrode 151. The organic layer 152 can include one or more light emitting structure (or light emitting element or an element) deposited on the anode electrode 151 in the order of a hole transfer layer and an electron transfer layer, or in the reverse order. For example, the hole transfer layer can include a hole transport layer, a hole injection layer, an electron blocking layer, a P-type electric charge generation layer and the like, but the embodiments of the present disclosure are not limited thereto. For example, the electron transfer layer can include an electron transport layer, an electron injection layer, a hole blocking layer, an N-type electric charge generation layer and the like, but the embodiments of the present disclosure are not limited thereto.

The organic layer 152 can be an organic light emitting layer, an inorganic light emitting layer, a quantum dot light emitting layer, a micro light emitting diode, a micro-mini light emitting diode and the like, but the embodiments of the present disclosure are not limited thereto. For example, the organic layer 152 of the display panel 100 according to an embodiment of the present disclosure can include an organic light emitting layer. The organic layer 152 can include a red light emitting layer, a green light emitting layer, and a blue light emitting layer, but the embodiments of the present disclosure are not limited thereto. The organic layer 152 can further include a white light emitting layer, but the embodiments of the present disclosure are not limited thereto.

The cathode electrode 153 can be disposed on the organic layer 152. The cathode electrode 153 can be a transparent electrode which transmits light, but the embodiments of the present disclosure are not limited thereto. For example, the cathode electrode 153 can include a transparent conductive material or metal such as ITO (Indium Tin Oxide) or IZO (Indium Zinc Oxide) through which the visible light is transmitted, but the embodiments of the present disclosure are not limited thereto.

A capping layer 156 can be further disposed on the cathode electrode 153. The capping layer 156 can minimize damage caused by an external light source to the cathode electrode 153 of the light emitting diode EL and the organic layer 152 below the cathode electrode 153. The capping layer 156 can be formed as an organic or inorganic layer.

The capping layer 156 can be disposed by using a material such as lithium fluoride (LiF) and the like as an inorganic layer, and can further include an organic layer, but the embodiments of the present disclosure are not limited thereto. For example, the capping layer 156 can be formed in a deposition structure in which an inorganic layer and an organic layer are deposited, and a thickness of the organic layer and a thickness of the inorganic layer can be different from each other. In such a case, the thickness of the organic layer can be greater than the thickness of the inorganic layer. As another example, the capping layer 156 can have two or more layers formed by depositing materials having different refractive indices. By doing so, the luminous efficiency of the display panel 100 can be improved.

A bank 154 can be disposed to expose the anode electrode 151. The bank 154 can define an opening (or the emitting region EA) of the sub-pixel SP, and can be disposed to cover an edge portion of the anode electrode 151. The organic layer 152 can be disposed within the opening of the sub-pixel SP. In other words, the organic layer 152 can be disposed on the anode electrode 151 exposed by the bank 154.

The bank 154 can be formed of an organic material such as a material including a black pigment and the like, a benzocyclobutene resin, a polyimide resin, an acrylic resin, or photosensitive polymer, but the embodiments of the present disclosure are not limited thereto. When the bank 154 is formed of a material including a black pigment, a black dye and the like, the bank 154 can be a black bank. When forming the bank 154 with a material including a black pigment, a black dye and the like, the bank 154 can block light from the outside or light reflected from the outside, thereby further improving brightness of the display device.

A spacer 155 can be further disposed on the bank 154. The spacer 155 can be formed of the same material as a material of the bank 154, but the embodiments of the present disclosure are not limited thereto. The spacer 155 can suppress or prevent mark or scratch defects on the display panel 100 by preventing sagging of a mask when performing a mask process.

The encapsulation unit 170 can be disposed on the bank 154 or the light emitting unit 150. The encapsulation unit 170 can include one or more insulation layers. For example, the encapsulation unit 170 can include a first inorganic encapsulation layer 171, a first organic encapsulation layer 172 disposed on the first inorganic encapsulation layer 171, and a second inorganic encapsulation layer 173 disposed on the organic encapsulation layer 172. The encapsulation unit 170 can include one or more inorganic material layers or one or more organic material layers. For example, the first inorganic encapsulation layer 171 and the second inorganic encapsulation layer 173 can include an inorganic material, and the organic encapsulation layer 172 can include an organic material, but the embodiments of the present disclosure are not limited thereto.

Even if the first inorganic encapsulation layer 171 and the second inorganic encapsulation layer 173 are disposed to extend up to an end of the non-display region NDA, the organic encapsulation layer 172 can terminate on an inside of the dam portion DMP. In other words, the organic encapsulation layer 172 may not cross the dam portion DMP, and can be disposed on an inside of a region surrounded by the dam portion DMP.

A touch unit 180 can be disposed on the encapsulation unit 170. The touch unit 180 can include a touch buffer layer 181, a first touch electrode 182, a first touch insulation layer 183, a black matrix BM, a second touch insulation layer 184, a second touch electrode 185, and a third touch insulation layer 186.

The touch buffer layer 181 can be disposed on the encapsulation unit 170. For example, the touch buffer layer 181 can be disposed on the second inorganic encapsulation layer 173. The touch buffer layer 181 can be formed of the same material as a material of the buffer layer 102, but the embodiments of the present disclosure are not limited thereto.

The first touch electrode 182 can be disposed on the touch buffer layer 181.

The first touch insulation layer 183 can be disposed on the first touch electrode 182. The first touch insulation layer 183 can be formed of silicon oxide SiOx or silicon nitride SiNx, or formed in a muti-layered structure of silicon oxide SiOx and silicon nitride SiNx, but the embodiments of the present disclosure are not limited thereto.

The black matrix BM can be disposed on the first touch insulation layer 183. The black matrix BM can include a material which can absorb the light. The black matrix BM can include a black pigment or a black dye, but is not limited thereto. The black matrix BM can prevent a light leakage defect and the like which can occur between the sub-pixels SP.

The second touch insulation layer 184 can be disposed on the black matrix BM. The second touch insulation layer 184 can include an organic insulation material. For example, the second touch insulation layer 184 can be formed of photo acryl, benzocyclobutene (BCB), polyimide (PI), or polyamide (PA), but is not limited thereto.

The second touch electrode 185 can be disposed on the second touch insulation layer 184. The second touch electrode 185 can include a first-a touch electrode 185a extending in the first direction DR1, and a first-b touch electrode 185b extending in the second direction DR2 which is different from the first direction.

The first touch electrode 182 can be electrically connected to the first-a touch electrode 185a through the contact hole formed on the insulation layer 184. For example, the first-a touch electrode 185a and the first touch electrode 182 can extend in the first direction DR1.

The first touch electrode 182 and the second touch electrode 185 can include a metal material. For example, the first touch electrode 182 and the second touch electrode 185 can be formed of titanium (Ti), nickel (Ni), aluminum (Al), or an alloy thereof, and can be formed in a three-layered structure of titanium (Ti)/aluminum (Al)/titanium (Ti), but the embodiments of the present disclosure are not limited thereto.

One among the first touch electrode 182 and the second touch electrode 185 can include a function of sensing a touch, and the other thereamong can include a driving function of the touch, but are not limited thereto.

The third touch insulation layer 186 can be disposed on the second touch electrode 185. The third touch insulation layer 186 can include the same material as a material of the first touch insulation layer 183, but is not limited thereto.

The microlens ML can be disposed on the third touch insulation layer 186. The microlens ML can have a hemispherical shape or a semicircular shape, but is not limited thereto. The shape of the microlens ML can vary according to a size and a shape of the emitting region EA.

By disposing the microlens ML, it is possible to secure a wide viewing angle characteristic, improve brightness, and block leaking light, reflected light and the like, thereby preventing the light leakage.

A center of the microlens ML can be mis-aligned with a center of the emitting region EA corresponding thereto. Nevertheless, some components of the light emitting unit 150 can be tilted, and accordingly, light emitted from the emitting region EA can proceed toward the microlens ML.

A lens protection layer 190 can be disposed on the microlens ML. The lens protection layer 190 can include an organic insulation material, but is not limited thereto. The lens protection layer 190 can protect the microlens ML by covering the microlens ML.

A refractive index of the lens protection layer 190 can be smaller than that of the microlens ML. Thus, due to a difference between the refractive index of the microlens ML and the refractive index of the lens protection layer 190, it becomes possible to prevent light which passes through the microlens ML from being reflected in a direction of the substrate 101.

In a region where the light emitting unit 150 is disposed, the second protection layer 112 can be formed such that some region of an upper surface of the second protection layer 112 has an inclination. At least some region of the light emitting unit 150 can be disposed on the second protection layer 112 of which at least some region is inclined. Therefore, each of the anode electrode 151 and the organic layer 152 can be tilted in at least some region. Each of the anode electrode 151 and the organic layer 152 can be tilted toward the microlens ML in at least some region.

In more detail, each of the anode electrode 151 and the organic layer 152 can be disposed on the second protection layer 112 of which at least some region is inclined. Each of the anode electrode 151 and the organic layer 152 can be disposed on the second protection layer 112 of which the entire region is inclined, but is not limited thereto.

The second protection layer 112 can include an inclined surface in some region. For example, the inclined surface of the second protection layer 112 can be formed through a slit mask process, without limitation thereto.

The anode electrode 151 and the organic layer 152 disposed on the inclined second protection layer 112 can be disposed to be inclined (leaned) in correspondence with the inclined second protection layer 112. Therefore, some region of the cathode electrode 153 disposed on the organic layer 152 can be inclined.

For example, the anode electrode 151 and the organic layer 152 can be inclined in the (1_1)th emitting region EA1_1, the (2_1)th emitting region EA2_1 and therearound with respect to a thickness direction of the display panel 100 (a third direction DR3). For example, a direction in which an upper surface of the anode electrode 151 and an upper surface of the organic layer 152 are headed can be inclined with respect to the thickness direction of the display panel 100 (the third direction DR3).

In the (1_1)th emitting region EA1_1, the (2_1)th emitting region EA2_1 and therearound, directions in which the anode electrode 151 and the organic layer 152 are inclined can be each different.

In FIG. 5, the anode electrode 151 and the organic layer 152 around the (1_1)th emitting region EA1_1 of the (1_1)th sub-pixel SP1_1 and the (2_1)th emitting region EA2_1 of the (2_1)th sub-pixel SP2_1 have been described, and all the description thereof can be applied to each sub-pixel SP.

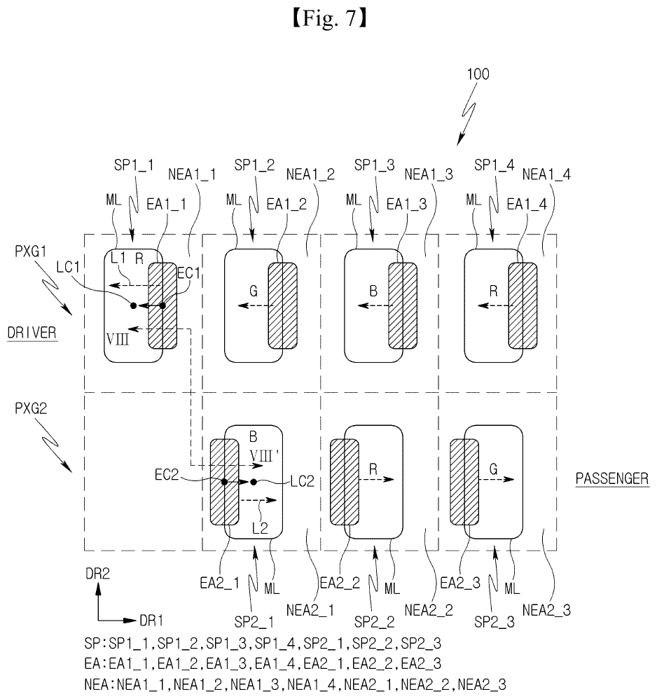

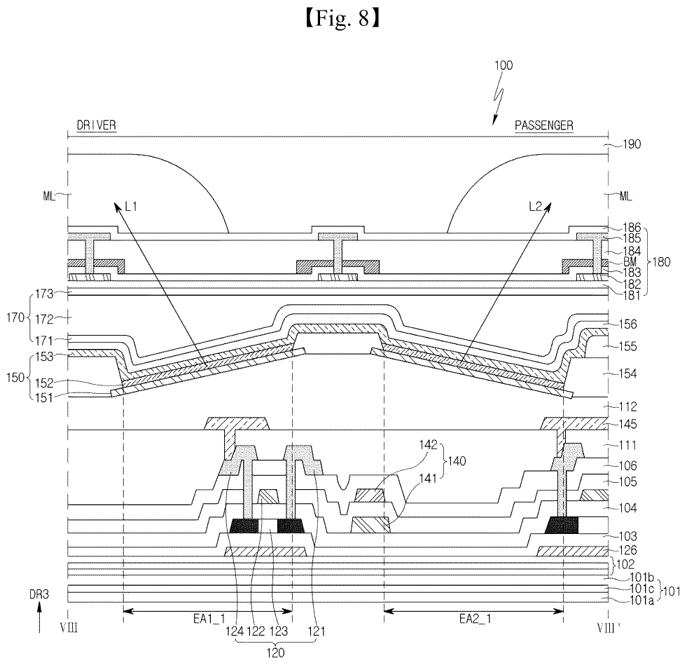

Therefore, light emitted from each sub-pixel SP can be inclined with respect to the thickness direction of the display panel 100 (the third direction DR3). For description thereof, views in FIGS. 7 and 8 are referred.

FIG. 7 is a plan view of the display panel according to an embodiment. FIG. 8 is a cross-sectional view taken along VIII-VIII′ line in FIG. 7. Each of FIG. 7 and FIG. 8 is substantially the same as FIGS. 4 and 5, but is a schematic diagram showing a path of lights L1 and L2 emitted from the light emitting unit 150.

Referring to FIGS. 7 and 8, the microlens ML and the emitting region EA corresponding thereto can be mis-aligned. In more detail, the center of the microlens ML and the center of the emitting region EA can be mis-aligned.

The center EC1 of the (1_1)th emitting region EA1_1 of the (1_1)th sub-pixel SP1_1 and the center LC1 of the microlens ML disposed in the (1_1)th sub-pixel SP1_1 can be mis-aligned. When viewed in a plan view, the center LC1 of the microlens ML can be mis-aligned from the center EC1 of the (1_1)th emitting region EA1_1 to the other side (a left side on the plane) of the first direction DR1.

Description on the mis-alignment of the (1_1)th sub-pixel SP1_1 can be applied substantially equally to the remaining sub-pixels (SP1_1, SP1_3 and SP1_4) of the first pixel group PXG1. However, in each of the remaining sub-pixels (SP1_1, SP1_2, SP1_3 and SP1_4) of the first pixel group PXG1, a degree in which the microlens ML and the emitting region EA are mis-aligned can differ from each other.

However, without limitation, a direction in which the center LC1 of the microlens ML and the center EC1 of the (1_1)th emitting region EA1_1 are mis-aligned can vary according to the designs.

A center EC2 of the (2_1)th emitting region EA2_1 of the (2_1)th sub-pixel SP2_1 and a center LC2 of the microlens ML disposed in the (2_1)th sub-pixel SP2_1 can be mis-aligned. When viewed in a plan view, the center LC2 of the microlens ML can be mis-aligned from the center EC2 of the (2_1)th emitting region EA2_1 to one side (a right side on a plane) of the first direction DR1.

The description of the mis-alignment of the (2_1)th sub-pixel SP2_1 can be applied substantially equally to the remaining sub-pixels SP2_2 and SP2_3 of the second pixel group PXG2. However, in each of the sub-pixels SP2_1, SP2_2 and SP2_3 of the second pixel group PXG2, a degree in which the microlens ML and the emitting region EA are mis-aligned can differ from each other.

However, without limitation, a direction in which the center LC2 of the microlens ML and the center EC2 of the (2_1)th emitting region EA2_1 are mis-aligned can vary according to the designs.

The opening (or the emitting region EA) of the sub-pixel SP and the light emitting unit 150 disposed around the opening can be inclined with respect to the thickness direction (the third direction DR3), and the lights L1 and L2 emitted from the light emitting unit 150 can proceed to a direction inclined with respect to the thickness direction (the third direction DR3).

As the microlens ML and the emitting region EA are mis-aligned, even if the lights L1 and L2 emitted from the light emitting unit 150 proceed with inclination with respect to the thickness direction (the third direction DR3), each light L1 and L2 can proceed toward the microlens ML.

The sub-pixels SP1_1, SP1_2, SP1_3 and SP1_4 disposed in the first pixel group PGX1 can emit the light L1 toward the left side (the other side in the first direction DR1) when viewed in a plan view. The sub-pixels SP2_1, SP2_2 and SP2_3 disposed in the second pixel group PXG2 can emit the light L2 toward the right side (one side in the first direction) when viewed in a plan view.

In other words, the light L1 emitted from the sub-pixels SP1_1, SP1_2, SP1_3 and SP1_4 of the first pixel group PXG1 can proceed with an inclination toward the other side in the first direction DR1 with respect to the thickness direction (the third direction DR3). The light L2 emitted from the sub-pixel SP2_1, SP2_2 and SP2_3 of the second pixel group PXG2 can proceed with an inclination toward the one side of the first direction DR1 with respect to the thickness direction (the third direction DR3).

A direction and a degree in which the microlens ML and the emitting region EA are mis-aligned can be changed according to a direction to which the light emitted from the sub-pixel SP of each of the pixel groups PXG1 and PXG2 proceeds.

When viewed in a plan view, the sub-pixels SP1_1, SP1_2, SP1_3 and SP1_4 disposed in the first pixel group PXG1, and the sub-pixels SP2_1, SP2_2 and SP2_3 disposed in the second pixel group PGX2 can emit light in each different direction, and accordingly, it is possible distinguish a screen being displayed to a driver sat on a driver's seat and a screen being displayed to a front passenger sat on a front passenger seat from each other, and to control each screen, and screens displayed to the driver and the passenger can differ from each other.

Even if the display panel 100 includes the notch portion NCP, it is possible to omit a portion of a mask covering the notch portion NCP over the course of depositing the inorganic insulation layer and the like. By omitting the portion of the mask covering the notch portion NCP, marks or scratches on the display panel 100 which can occur by the corresponding portion of the mask can be suppressed and prevented. Moreover, defect can be prevented, a life-span of the display device 1 can be improved, and production energy used to produce the display device 1 can be reduced.

By omitting the portion of the mask covering the notch portion NCP, at least one among the inorganic insulation layers disposed on the substrate 101 can extend to the end of the notch non-display region N_NDA around the notch portion NCP. Here, the end of the non-display region N_NDA can mean an end (or a tip end) of the substrate 101, and thus, an end (or a tip end) of the inorganic layers disposed on the substrate 101.

For example, the first inorganic encapsulation layer 171 and the second inorganic encapsulation layer 173 can be disposed on the substrate 101 through chemical vapor deposition (CVD), and if the portion of the mask covering the notch portion NCP is omitted, the first inorganic encapsulation layer 171 and the second inorganic encapsulation layer 173 can extend to the end of the notch non-display region N_NDA around the notch portion NCP.

However, without limitation thereto, at least one among the inorganic insulation layers disposed on the substrate 101 can extend to the end of the non-display region NDA in all of the regions of the non-display region NDA.

Hereinafter, a cross-sectional structure of the non-display region NDA of the display device 1 will be described. The same content provided in the description of the cross-sectional structure of the display region DA will be briefly described or omitted.

FIG. 9 is a cross-sectional view taken along A-A′ line in FIG. 1 and illustrates a cross-sectional structure of the first non-display region NDA1.

Referring to FIGS. 1, 5 and 9, the display panel 100 can include the substrate 101, the buffer layer 102, the first insulation layer 103, the second insulation layer 104, the third insulation layer 105, the fourth insulation layer 106, the first protection layer 111, the second protection layer 112, the bank 154, the encapsulation unit 170, the touch buffer layer 181, the first touch insulation layer 183 and the third touch insulation layer 186 disposed sequentially in the first non-display region NDA.

In the first non-display region NDA, the display panel 100 can further include a gate control transistor G120, a low potential voltage line VSSL, the dam portion DMP, and an anti-crack pattern CSP.

The gate control transistor G120 has substantially the same configuration as that of the transistor 120 of the sub-pixel SP, and can be formed together with the transistor 120 of the sub-pixel SP through the same process, but is not limited thereto.

The gate control transistor G120 can include a control source electrode G121, a control gate electrode G122, a control semiconductor layer G123, and a control drain electrode G124.

The low potential voltage line VSSL can be disposed on the fourth insulation layer 106 in the non-display region NDA. The low potential voltage line VSSL can be disposed on the same layer as the layer of the source electrode 121 and the drain electrode 124, can include the same material as the material of the source electrode 121 and the drain electrode 124, and can be formed together with the source electrode 121 and the drain electrode 124 using one mask through the same process, but is not limited thereto.

Although not illustrated, the low potential voltage line VSSL can further include an additional low potential connection electrode for contacting the cathode electrode 153. The low potential connection electrode can be disposed on a different layer from a layer of the low potential voltage line VSSL, and can include a different material from a material of the low potential voltage line VSSL, but is not limited thereto. Through the low potential connection electrode, the low potential voltage line VSSL can be electrically connected to the anode electrode 151 of the light emitting unit 150 disposed in the display region DA across other wirings disposed on the same layer.

The dam portion DMP can include a first dam DM1 and a second dam DM2. The first dam DM1 and the second dam DM2 can overlap the low potential voltage line VSSL. The first dam DM1 can be disposed outside the second dam DM2, but is not limited thereto.

The first dam DM1 can be formed in a multi-layered structure. Each layer of the first dam DM1 can include the same material as a material of the second protection layer 112, the bank 154, and the spacer 155, and can be formed together with the second protection layer 112, the bank 154, and the spacer 155 using one mask through the same process, but is not limited thereto.

The second dam DM2 can be formed in a multi-layered structure. Each layer of the second dam DM2 can include the same material as a material of the second protection layer 112 and the bank 154, and can be formed together with the second protection layer 112 and the bank 154 using one mask through the same process, but is not limited thereto.

The anti-crack pattern CSP can be disposed at an outermost position of the non-display region NDA. Although not illustrated, the anti-crack pattern can be provided in plural number, but is not limited thereto. The anti-crack pattern CSP can be defined as at least one among the inorganic layers disposed on the substrate 101 is recessed.

For example, the anti-crack pattern CSP can be defined as the first insulation layer 103, the second insulation layer 104, the third insulation layer 105, the fourth insulation layer 106, the first inorganic encapsulation layer 171, the second inorganic encapsulation layer 173, the touch buffer layer 181, the first touch insulation layer 183, and the third touch insulation layer 186 are recessed, but is not limited thereto. For example, around the anti-crack pattern CSP, at least one among the first protection layer 111, the second protection layer 112, and the bank 154 can be further disposed. In this case, the anti-crack pattern CSP can be defined by additionally recessing at least one among the first protection layer 111, the second protection layer 112, and the bank 154, as well as recessing the first insulation layer 103, the second insulation layer 104, the third insulation layer 105, the fourth insulation layer 106, the first inorganic encapsulation layer 171, the second inorganic encapsulation layer 173, the touch buffer layer 181, the first touch insulation layer 183, and the third touch insulation layer 186. At least some of the inorganic layers disposed on the substrate 101 can extend up to the end of the non-display region NDA. In other words, at least some of the inorganic layers disposed on the substrate 101 can extend up to an end of the substrate 101.

The buffer layer 102, the first insulation layer 103, the second insulation layer 104, the third insulation layer 105, the fourth insulation layer 106, the first inorganic encapsulation layer 171, the second inorganic encapsulation layer 173, the touch buffer layer 181, the first touch insulation layer 183, and the third touch insulation layer 186 can extend to an end of the first non-display region NDA1.

In other words, in the first non-display region NDA1, the buffer layer 102, the first insulation layer 103, the second insulation layer 104, the third insulation layer 105, the fourth insulation layer 106, the first inorganic encapsulation layer 171, the second inorganic encapsulation layer 173, the touch buffer layer 181, the first touch insulation layer 183, and the third touch insulation layer 186 can extend up to the end of the substrate 101.

In the first non-display region NDA1, the buffer layer 102, the first insulation layer 103, the second insulation layer 104, the third insulation layer 105, the fourth insulation layer 106, the first inorganic encapsulation layer 171, the second inorganic encapsulation layer 173, the touch buffer layer 181, the first touch insulation layer 183, and the third touch insulation layer 186 can substantially cover the entire region of the substrate 101.

An end (or a side surface) of each of the substrate 101, the buffer layer 102, the first insulation layer 103, the second insulation layer 104, the third insulation layer 105, the fourth insulation layer 106, the first inorganic encapsulation layer 171, the second inorganic encapsulation layer 173, the touch buffer layer 181, the first touch insulation layer 183, and the third touch insulation layer 186 can be aligned with each other, but is not limited thereto.

In the first non-display region NDA1, at least one among the buffer layer 102, the first insulation layer 103, the second insulation layer 104, the third insulation layer 105, the fourth insulation layer 106, the first inorganic encapsulation layer 171, the second inorganic encapsulation layer 173, the touch buffer layer 181, the first touch insulation layer 183, and the third touch insulation layer 186 may not extend to the end of the substrate 101, without limitation thereto.

For example, in the first non-display region NDA1, the buffer layer 102, the first insulation layer 103, the second insulation layer 104, the third insulation layer 105, and the fourth insulation layer 106 can extend to the end of the substrate 101; the first inorganic encapsulation layer 171 and the second inorganic encapsulation layer 173 can extend up to the dam portion DMP; and the touch buffer layer 181, the first touch insulation layer 183, and the third touch insulation layer 186 can extend up to shortly before the dam portion DMP. For example, between the dam portion DMP and the anti-crack pattern CSP, the buffer layer 102, the first insulation layer 103, the second insulation layer 104, the third insulation layer 105, and the fourth insulation layer 106 can be disposed, while the first inorganic encapsulation layer 171 and the second inorganic encapsulation layer 173, the touch buffer layer 181, the first touch insulation layer 183, and the third touch insulation layer 186 may not be disposed therebetween.

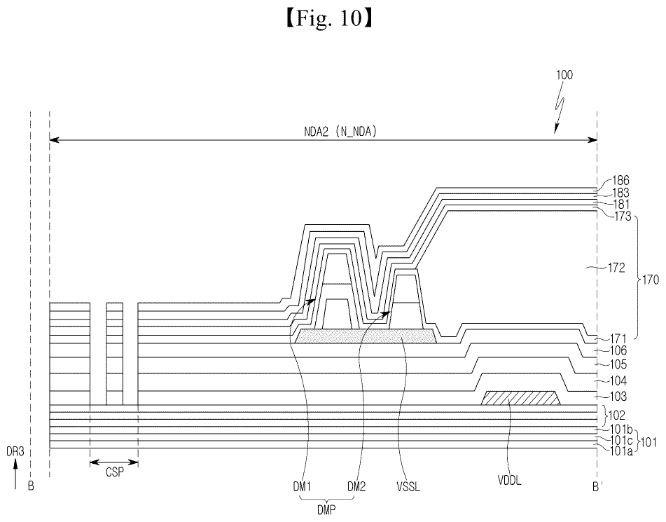

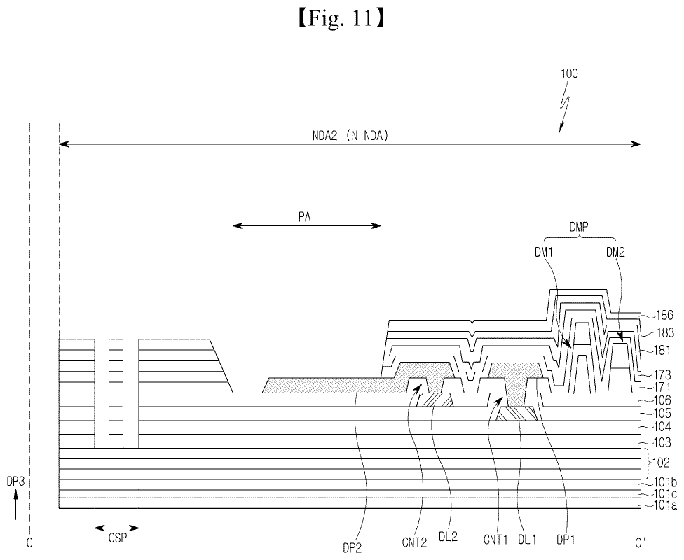

FIG. 10 is a cross-sectional view taken along B-B′ line in FIG. 3. FIG. 11 is a cross-sectional view taken along C-C′ line in FIG. 3.

Particularly, FIGS. 10 and 11 illustrate a cross-sectional structure of the second non-display region NDA2, and illustrate a cross-sectional structure of the notch non-display region N_NDA of the second non-display region NDA2, however, the description thereof can be applied substantially equally to the extending non-display region E_NDA. However, the notch non-display region N_NDA and the extending non-display region E_NDA can have each different cross-sectional structure, without limitation thereto.

Referring to FIGS. 3, 5, 10 and 11, in the notch non-display region N_NDA, the display panel 100 can include the substrate 101, the buffer layer 102, the first insulation layer 103, the second insulation layer 104, the third insulation layer 105, the fourth insulation layer 106, the first protection layer 111, the second protection layer 112, the bank 154, the encapsulation unit 170, the touch buffer layer 181, the first touch insulation layer 183, and the third touch insulation layer 186 disposed sequentially.

In the notch non-display region N_NDA, the display panel 100 can further include the high potential voltage line VDDL, the low potential voltage line VSSL, the dam portion DMP, the plurality of pads VSSP, VDDP and DP disposed in the pad region PA, the data line DL (DL1 and DL2), and the anti-crack pattern CSP.

The high potential voltage line VDDL can be disposed on the buffer layer 102 in the non-display region NDA, and can be covered by the first insulation layer 103. The high potential voltage line VDDL can include the same material as a material of the first light shielding layer 126, and can be formed together with the first light shielding layer 126 using one mask through the same process, but is not limited thereto.

Although not illustrated, the high potential voltage pad VDDP can be disposed on the same layer as the layer of the source electrode 121 and the drain electrode 124, can include the same material as the material of the source electrode 121 and the drain electrode 124, and can be formed together with the source electrode 121 and the drain electrode 124 using one mask through the same process, but is not limited thereto.

In this case, the high potential voltage pad VDDP can be electrically connected to the high potential voltage line VDDL by contacting the contact hole S_CNT exposing the high potential voltage line VDDL.

The high potential voltage line VDDL can further include the high potential connection electrode. The high potential connection electrode (not illustrated) can be disposed on a different layer from a layer of the high potential voltage line VDDL. For example, the high potential connection electrode can be disposed between the second insulation layer 104 and the third insulation layer 105. The high potential connection electrode can electrically connect the high potential voltage line VDDL and the anode electrode 151 across wirings disposed on the same layer as a layer of the high potential voltage line VDDL. The high potential connection electrode can be electrically connected to the anode electrode 151 across wirings disposed on the same layer as a layer of the high potential voltage line VDDL.

When the high potential voltage line VDDL is formed on the same layer as the layer of the high potential voltage pad VDDP and is integrally formed with the high potential voltage pad VDDP, the high potential voltage line VDDL can further include the high potential connection electrode. The high potential connection electrode can electrically connect the high potential voltage line VDDL and the anode electrode 151 across wirings disposed on the same layer as a layer of the high potential voltage line VDDL.

The first data pad DP1 and the second data pad DP2 can be disposed on the fourth insulation layer 106. The first data pad DP1 and the second data pad DP2 can be disposed on the same layer as the layer of the source electrode 121 and the drain electrode 124, can include the same material as a material of the source electrode 121 and the drain electrode 124, and can be formed together with the source electrode 121 and the drain electrode 124 using one mask through the same process, but is not limited thereto.

The first data line DL1 can be disposed on the second insulation layer 104 in the non-display region NDA, and can be covered by the third insulation layer 105. The first data line DL1 can include the same material as a material of the gate electrode 122, and can be formed together with the gate electrode 122 using one mask through the same process, but is not limited thereto.

The display panel 100 can further include a first data connection line. The first data connection line can be disposed on a different layer from a layer of the first data line DL1, and can electrically connect the first data line DL1 to the thin film transistor 120 of the display region DA.

The second data line DL2 can be disposed on the third insulation layer 105 in the non-display region NDA, and can be covered by the fourth insulation layer 106. The second data line DL2 can include the same material as a material of the second storage electrode 142, and can be formed together with the second storage electrode 142 using one mask through the same process, but is not limited thereto.

The display panel 100 can further include the first data connection line. The first data connection line can be disposed on a different layer from the layer of the first data line DL1, and can electrically connect the first data line DL1 to the thin film transistor 120 of the display region DA.

The first data line DL1 can be electrically connected to the first data pad DP1 by contacting the first data pad DP1 through the first data contact hole CNT1. The second data line DL2 can be electrically connected to the second data pad DP2 by contacting the second data pad DP2 through the second data contact hole CNT2.

The anti-crack pattern CSP can be disposed outside the pad region PA. The anti-crack pattern CSP can be disposed between the pad region PA and an end of the second non-display region NDA2.

At least some of the inorganic layers disposed on the substrate 101 can extend to the end of the second non-display region NDA2. In other words, at least some of the inorganic layers disposed on the substrate 101 in the notch non-display region N_NDA and the extending non-display region E_NDA can extend to the end of the substrate 101.

In the notch non-display region N_NDA, the buffer layer 102, the first insulation layer 103, the second insulation layer 104, the third insulation layer 105, the fourth insulation layer 106, the first inorganic encapsulation layer 171, the second inorganic encapsulation layer 173, the touch buffer layer 181, the first touch insulation layer 183, and the third touch insulation layer 186 can extend to the end of the substrate 101.

In the notch non-display region N_NDA, the buffer layer 102, the first insulation layer 103, the second insulation layer 104, the third insulation layer 105, the fourth insulation layer 106, the first inorganic encapsulation layer 171, the second inorganic encapsulation layer 173, the touch buffer layer 181, the first touch insulation layer 183, and the third touch insulation layer 186 can substantially cover the entire region of the substrate 101 except the pad region PA.

An end (or a side surface) of each of the substrate 101, the buffer layer 102, the first insulation layer 103, the second insulation layer 104, the third insulation layer 105, the fourth insulation layer 106, the first inorganic encapsulation layer 171, the second inorganic encapsulation layer 173, the touch buffer layer 181, the first touch insulation layer 183, and the third touch insulation layer 186 can be aligned with each other, but is not limited thereto.

However, the plurality of pads VSSP, VDDP and DP may not be covered by the plurality of inorganic layers. The plurality of inorganic layers disposed on the fourth insulation layer 106 can expose the plurality of pads VSSP, VDDP and DP. The plurality of inorganic layers disposed on the fourth insulation layer 106 may not be disposed in the pad region PA.

For example, the first inorganic encapsulation layer 171, the second inorganic encapsulation layer 173, the touch buffer layer 181, the first touch insulation layer 183, and the third touch insulation layer 186 can be disposed to the end of the substrate 101 in the notch non-display region N_NDA, but may not be disposed in the pad region PA. Therefore, the plurality of pads VSSP, VDDP and DP disposed on the fourth insulation layer 106 can be exposed, and can be electrically connected to the flexible film COF as the display panel 100 is attached to the flexible film COF.

However, in the extending non-display region E_NDA, at least one among the buffer layer 102, the first insulation layer 103, the second insulation layer 104, the third insulation layer 105, the fourth insulation layer 106, the first inorganic encapsulation layer 171, the second inorganic encapsulation layer 173, the touch buffer layer 181, the first touch insulation layer 183, and the third touch insulation layer 186 may not extend to the end of the substrate 101, without limitation thereto.

For example, in the extending non-display region E_NDA, the buffer layer 102, the first insulation layer 103, the second insulation layer 104, the third insulation layer 105, and the fourth insulation layer 106 can extend to the end of the substrate 101; the first inorganic encapsulation layer 171 and the second inorganic encapsulation layer 173 can extend up to the dam portion DMP; and the touch buffer layer 181, the first touch insulation layer 183, and the third touch insulation layer 186 can extend up to shortly before the dam portion DMP. For example, between the dam portion DMP and the anti-crack pattern CSP, the buffer layer 102, the first insulation layer 103, the second insulation layer 104, the third insulation layer 105, and the fourth insulation layer 106 can be disposed, while the first inorganic encapsulation layer 171 and the second inorganic encapsulation layer 173, the touch buffer layer 181, the first touch insulation layer 183, and the third touch insulation layer 186 may not be disposed therebetween.

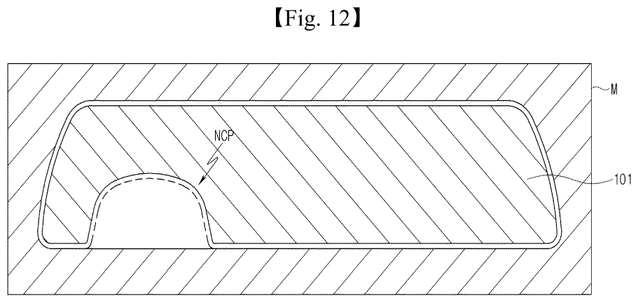

FIG. 12 is a schematic view illustrating one step of a method for manufacturing a display device according to an embodiment.

Referring to FIGS. 10 to 12, a protrusion of the mask M for covering the notch portion NCP can be omitted over the course of depositing the inorganic layer and the like on the substrate 101 which includes the notch portion NCP. Therefore, a periphery of the notch portion NCP of the substrate 101 may not be covered by the mask M, but be opened.

As the protrusion of the mask M is omitted, mark and scratch defects which can occur by the protrusion of the mask M may be suppressed or prevented. Further, the defects of the display device 1 can be prevented, a life-span of the display device 1 can be improved, and production energy used to produce the display device 1 can be reduced.

In other words, as the substrate 101 and the display panel 100 include the notch portion NCP, the user can be provided with improved aesthetic and convenience. Over the course of manufacturing the display panel, one portion (the protrusion) of the mask M for covering the notch portion NCP can be omitted, and thus, mark and scratch defects of the display panel can be suppressed or prevented. As a result, the reliability of the display device 1 can be improved.

In addition, as one portion (the protrusion) of the mask M for covering the notch portion NCP is omitted, in the notch non-display region N-NDA, the buffer layer 102, the first insulation layer 103, the second insulation layer 104, the third insulation layer 105, the fourth insulation layer 106, the first inorganic encapsulation layer 171, the second inorganic encapsulation layer 173, the touch buffer layer 181, the first touch insulation layer 183, and the third touch insulation layer 186 can extend to the end of the substrate 101.

In FIG. 12, it is illustrated that the mask M does not overlap the substrate 101, but is not limited thereto, and the mask M can be disposed to overlap a portion of the substrate 101. For example, the mask M can overlap an edge of the substrate 101 in the remaining region except the notch portion NCP.

Hereinafter, other embodiments of the present disclosure will be described. Components substantially the same to the components described referring to FIGS. 1 to 12 among the components included in the other embodiments will be given with the same reference numerals and redundant components can be omitted or briefly described.

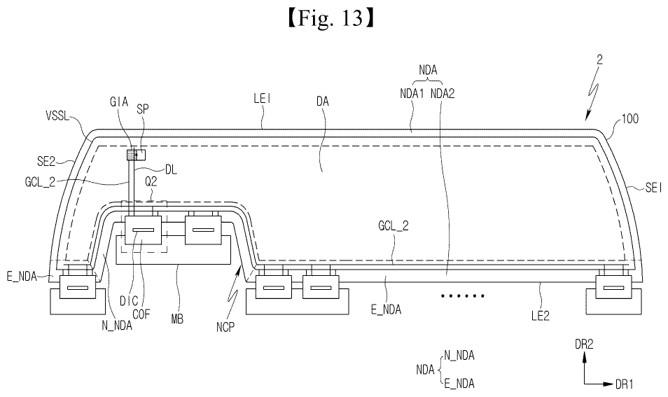

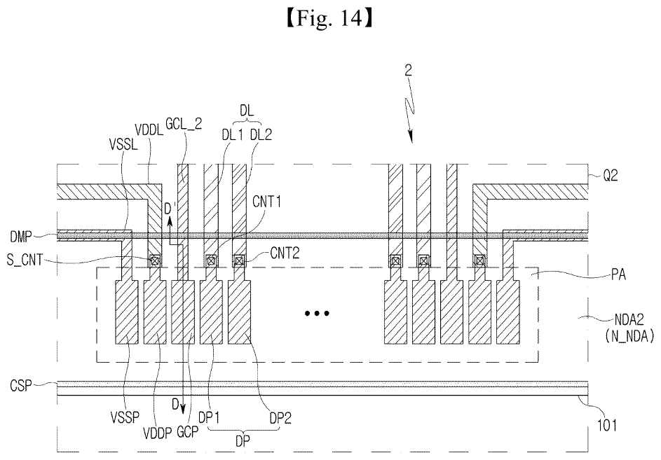

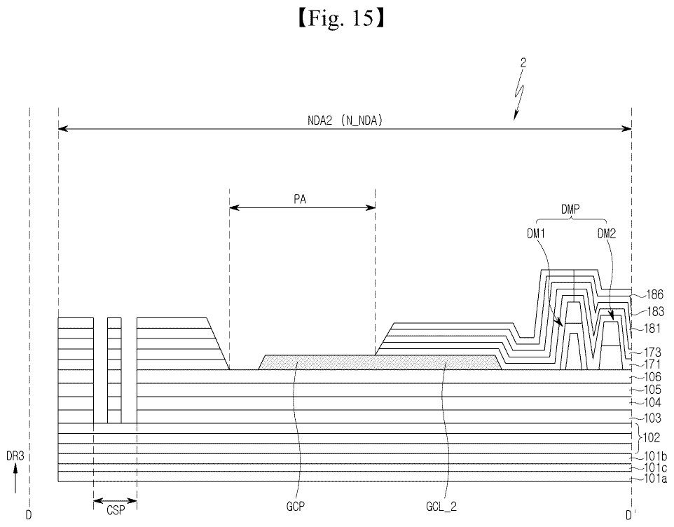

FIG. 13 is a plan view of a display device according to another embodiment. FIG. 14 is an enlarged view of Q2 region in FIG. 13. FIG. 15 is a cross-sectional view taken along D-D′ line in FIG. 14.

More specifically, FIG. 14 is a view in which the flexible film COF, the main substrate MB, and the driver IC DIC are omitted in the Q2 region of the display device 2 according to another embodiment.

Referring to FIGS. 13 to 15, in the display device 2 according to the present disclosure, a separate gate driver GIP (refer to FIG. 1) is not disposed in the non-display region NDA, and a pixel gate driver GIA can be disposed in the display region DA.

The pixel gate driver GIA can be provided in plural number, and each of the pixel gate drivers GIA can be connected to the plurality of sub-pixels SP, respectively. The pixel gate driver GIA can be disposed on the sub-pixels SP adjacent to each other.

For example, the pixel gate driver GIA can be disposed between the sub-pixels SP adjacent to each other in the first direction DR1. The sub-pixel SP and the pixel gate driver GIA can be repeatedly and alternately disposed along the first direction DR1. The sub-pixel SP can be repeatedly and continuously disposed along the second direction DR2. The pixel gate driver GIA can be repeatedly and continuously disposed along the second direction DR2.

The pixel gate driver GIA can play substantially the same role as the role of the gate driver GIP (refer to FIG. 1). The pixel gate driver GIA can include at least one transistor.

The pixel gate driver GIA can be electrically connected to the sub-pixel SP adjacent thereto.

The pixel gate driver GIA can receive a gate control signal from the driver IC DIC through the gate control line GCL_2. The pixel gate driver GIA can generate a scan signal and a light emission signal (or a light emission control signal) based on the gate control signal. By doing so, the pixel gate driver GIA can control an operation of an adjacent sub-pixel SP.

As the pixel gate driver GIA is disposed in the display region DA, it is possible to minimize the non-display region NDA or the bezel region, and to provide improved aesthetic to the user.

The display device 2 can further include a gate control line GCL_2 and a gate control pad GCP.

The gate control line GCL_2 can be disposed in the non-display region NDA. The gate control line GCL_2 can be disposed in the second non-display region NDA2, but is not limited thereto. The gate control line GCL_2 can be disposed along an extending direction of the second non-display region NDA2.

The gate control line GCL_2 can be electrically connected to the plurality of pixel gate drivers GIA disposed in the display region DA.

The gate control pad GCP can be disposed in the pad region PA. It is illustrated that the gate control pad GCP is disposed between the high potential voltage pad VDDP and the data pad DP in the pad region PA, however, is not limited thereto, and an arrangement position of the gate control pad GCP can vary according to the design.

The gate control pad GCP can include the same material as a material of the gate control line GCL_2, but is not limited thereto. The gate control pad GCP and the gate control line GCL can be integrally formed, but are not limited thereto.

The gate control pad GCP and the gate control line GCL can be disposed on the fourth insulation layer 106 in the non-display region NDA. The gate control pad GCP and the gate control line GCL can be disposed on the same layer as the layer of the source electrode 121 (refer to FIG. 5) and the drain electrode 124 (refer to FIG. 5), can include the same material as the material of the source electrode 121 and the drain electrode 124, and can be formed together using one mask through the same process, but are not limited thereto.

In this case, at least some of the inorganic layers disposed on the substrate 101 can extend to the end of the second non-display region NDA2. In other words, at least some of the inorganic layers disposed on the substrate 101 in the notch non-display region N_NDA and the extending non-display region E_NDA can extend to the end of the substrate 101.

In the notch non-display region N_NDA, the buffer layer 102, the first insulation layer 103, the second insulation layer 104, the third insulation layer 105, the fourth insulation layer 106, the first inorganic encapsulation layer 171, the second inorganic encapsulation layer 173, the touch buffer layer 181, the first touch insulation layer 183, and the third touch insulation layer 186 can extend to the end of the substrate 101.

In the notch non-display region N_NDA, the buffer layer 102, the first insulation layer 103, the second insulation layer 104, the third insulation layer 105, the fourth insulation layer 106, the first inorganic encapsulation layer 171, the second inorganic encapsulation layer 173, the touch buffer layer 181, the first touch insulation layer 183, and the third touch insulation layer 186 can substantially cover the entire region of the substrate 101 except the pad region PA.

An end (or a side surface) of each of the substrate 101, the buffer layer 102, the first insulation layer 103, the second insulation layer 104, the third insulation layer 105, the fourth insulation layer 106, the first inorganic encapsulation layer 171, the second inorganic encapsulation layer 173, the touch buffer layer 181, the first touch insulation layer 183, and the third touch insulation layer 186 can be aligned with each other, but is not limited thereto.

However, the plurality of pads VSSP, VDDP and DP may not be covered by the plurality of inorganic layers. The plurality of inorganic layers disposed on the fourth insulation layer 106 can expose the plurality of pads VSSP, VDDP and DP. The plurality of inorganic layers disposed on the fourth insulation layer 106 may not be disposed in the pad region PA.

For example, the first inorganic encapsulation layer 171, the second inorganic encapsulation layer 173, the touch buffer layer 181, the first touch insulation layer 183, and the third touch insulation layer 186 can be disposed to the end of the substrate 101 in the notch non-display region N_NDA, but may not be disposed in the pad region PA. Therefore, the plurality of pads VSSP, VDDP and DP disposed on the fourth insulation layer 106 can be exposed, and can be electrically connected to the flexible film COF as the display panel 100 is attached to the flexible film COF.

In FIG. 15, only a cross-sectional view of the notch non-display region N_NDA is illustrated, however, the description thereof can be applied equally to the extending non-display region E_NDA.

In this case, as the substrate 101 includes the notch portion NCP, the user can be provided with improved aesthetic and convenience.

The protrusion of the mask M (refer to FIG. 12) can be omitted, and as a result, mark or scratch defects which can occur by the protrusion of the mask M can be suppressed and prevented.

Over the course of manufacturing the display panel, one portion (the protrusion) of the mask M for covering the notch portion NCP can be omitted, and thus, mark and scratch defects of the display panel can be suppressed or prevented. As a result, the reliability of the display device 2 can be improved. Moreover, defect can be prevented, a life-span of the display device 2 can be improved, and production energy used to produce the display device 2 can be reduced.

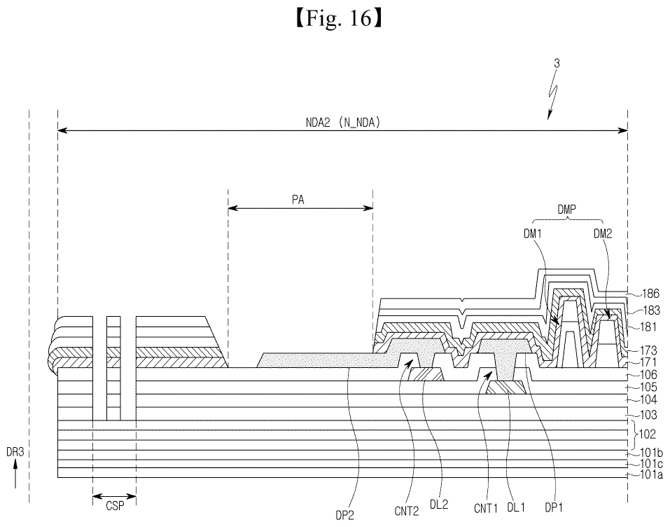

FIG. 16 is a cross-sectional view of a display device according to another embodiment of the present disclosure, and illustrates a cross-section of the notch non-display region N_NDA in the second non-display region NDA2.

Referring to FIG. 16, in a display device 3 according to the present embodiment, the buffer layer 102, the first insulation layer 103, the second insulation layer 104, the third insulation layer 105, the fourth insulation layer 106, the first inorganic encapsulation layer 171, the second inorganic encapsulation layer 173, the touch buffer layer 181, the first touch insulation layer 183, and the third touch insulation layer 186 disposed on the substrate 101 can extend to the end of the substrate 101.

In this case, the inorganic layer formed through chemical vapor deposition (CVD) can be disposed beyond the end of the non-display region NDA, and can cover at least one side surface (a side surface exposed on a tip end of the non-display region NDA) of one among the inorganic layers disposed at a lower portion.

For example, the first inorganic encapsulation layer 171 and the second inorganic encapsulation layer 173 can be formed through the chemical vapor deposition (CVD), and the first inorganic encapsulation layer 171 and the second inorganic encapsulation layer 173 can cover a side surface of the fourth insulation layer 106 at the end of the notch non-display region N_NDA. However, the embodiment of the present disclosure is not limited thereto, and the first inorganic encapsulation layer 171 and the second inorganic encapsulation layer 173 can cover at least one side surface of one among the other inorganic layers disposed below the fourth insulation layer 106.

In this case, as the substrate 101 uses the notch portion NCP, the user can be provided with improved aesthetic and convenience.

The protrusion of the mask M (refer to FIG. 12) can be omitted, and as a result, mark or scratch defects which can occur by the protrusion of the mask M can be suppressed and prevented.

As the protrusion of the mask M (refer to FIG. 12) is omitted, at least one among the inorganic layers formed through the chemical deposition around the notch portion NCP exposed by the mask M (refer to FIG. 12) can be formed to cover an exposed side surface of at least one among the inorganic layers disposed at a lower portion in the non-display region NDA.

Over the course of manufacturing the display panel, one portion (the protrusion) of the mask M for covering the notch portion NCP can be omitted, and thus, mark and scratch defects of the display panel can be suppressed or prevented. As a result, the reliability of the display device 3 can be improved. Moreover, defect can be prevented, a life-span of the display device 3 can be improved, and production energy used to produce the display device 3 can be reduced.

The display device according to various embodiments of the present disclosure can be described as below.

One or more embodiments of the present disclosure provide a display device, including a display panel having a notch portion and including a display region and a non-display region around the display region; and a printed circuit film attached to the display panel, and the display panel can include a substrate; at least one panel inorganic layer disposed on the substrate; a light emitting unit disposed on the at least one panel inorganic layer; and an encapsulation unit disposed on the light emitting unit, where the non-display region can include a notch non-display region disposed around the notch portion, and the encapsulation unit can be disposed up to an end of the notch non-display region.

According to various embodiments of the present disclosure, the non-display region can further include an extending non-display region extending from the notch non-display region, and the printed circuit film can be provided in plural number and at least one printed circuit film can be attached on the extending non-display region.

According to various embodiments of the present disclosure, the notch non-display region can include a pad region to which the printed circuit film is attached.

According to various embodiments of the present disclosure, the encapsulation unit can include a first inorganic encapsulation layer on the at least one panel inorganic layer, an organic encapsulation layer on the first inorganic encapsulation layer, and a second inorganic encapsulation layer on the organic encapsulation layer, and each of the first inorganic encapsulation layer and the second inorganic encapsulation layer can extend up to the end of the notch non-display region.

According to various embodiments of the present disclosure, the first inorganic encapsulation layer and the second inorganic encapsulation layer may not be disposed in the pad region.

According to various embodiments of the present disclosure, the display device can further include a low potential voltage line, a high potential voltage line, and a data line electrically connected to the pad region, and in the non-display region below the display region, the high potential voltage line can be disposed between the low potential voltage line and the display region.

According to various embodiments of the present disclosure, the low potential voltage line can surround the display region.

According to various embodiments of the present disclosure, the non-display region on a left side or a right side of the display region can further include a gate driver between the low potential voltage line and the display region.

According to various embodiments of the present disclosure, the display device can further include a pixel gate driver disposed in the display region; and a gate control line electrically connecting the pad region and the pixel gate driver to each other.

According to various embodiments of the present disclosure, the gate control line can be disposed between the low potential voltage line and the display region.

According to various embodiments of the present disclosure, the display device can further include a dam portion disposed in the non-display region and overlapping the low potential voltage line, and the organic encapsulation layer can terminate on an inside of the dam portion.

According to various embodiments of the present disclosure, the display device can further include an anti-crack pattern disposed between an end of the display panel and the dam portion, and the anti-crack pattern can penetrate at least one panel inorganic layer.

Another embodiment of the present disclosure can provide a display device, including a substrate including a display region having a plurality of sub-pixels and a non-display region around the display region; at least one panel inorganic layer disposed on the substrate; a light emitting unit disposed on the at least one panel inorganic layer; an encapsulation unit disposed on the light emitting unit; a display panel including a touch unit disposed on the encapsulation unit; and a microlens disposed on a light emitting region of the sub-pixels, where the encapsulation unit can extend up to an end of the non-display region.

According to various embodiments of the present disclosure, a center of the microlens and a center of the light emitting region can be mis-aligned.

According to various embodiments of the present disclosure, the plurality of sub-pixels can include a first pixel group in which the center of the microlens is mis-aligned toward another side in a first direction with respect to the center of the light emitting region; and a second pixel group in which the center of the microlens is mis-aligned toward one side in the first direction with respect to the center of the light emitting region.

According to various embodiments of the present disclosure, each of the first pixel group and the second pixel group can extend along the first direction, and the first pixel group and the second pixel group can be spaced apart in a second direction intersecting the first direction.

According to various embodiments of the present disclosure, the light emitting unit can further include an anode electrode disposed on the at least one panel inorganic layer, and the anode electrode can be tilted toward the microlens.

According to various embodiments of the present disclosure, the substrate can include a notch portion, the non-display region can include a notch non-display region disposed around the notch portion, and the encapsulation unit can be disposed up to an end of the notch non-display region.

According to various embodiments of the present disclosure, the display device can further include a plurality of printed circuit films, the non-display region can further include an extending non-display region extending from the notch non-display region, and at least one printed circuit film can be attached on the extending non-display region.

According to various embodiments of the present disclosure, the non-display region can include a pad region to which the printed circuit film is attached, the encapsulation unit can include a first inorganic encapsulation layer on the at least one panel inorganic layer, an organic encapsulation layer on the first inorganic encapsulation layer, and a second inorganic encapsulation layer on the organic encapsulation layer, each of the first inorganic encapsulation layer and the second inorganic encapsulation layer can extend up to the end of the notch non-display region, and the first inorganic encapsulation layer and the second inorganic encapsulation layer may not be disposed in the pad region.

The embodiments of the present disclosure have been described with reference to accompanying drawings. Those of ordinary skill in the art will recognize that the present disclosure can be embodied in other specific forms without departing from its spirit or essential characteristics. The described embodiments are to be considered in all respects only as illustrative and not restrictive. The scope of the present disclosure is therefore indicated by the appended claims rather than by the foregoing description. All changes which come within meaning and range of equivalency of the claims are to be embraced within the scope of the present disclosure.

### REFERENCE NUMERALS

1: display device
100: display panel
101: substrate
NCP: notch portion
DA: display region
NDA: non-display region
NDA1: first non-display region
NDA2: second non-display region
N_NDA: notch non-display region
E_NDA: extending non-display region
PA: pad region
SP: sub-pixel
EA: emitting region
NEA: non-emitting region
ML: microlens
150: light emitting unit
170: encapsulation unit

What is claimed is:

1. A display device, comprising:
a display panel having a notch portion, a display region and a non-display region around the display region; and
a printed circuit film coupled to the display panel,
wherein the display panel includes:
a substrate;
at least one panel inorganic layer disposed on the substrate;
a light emitting unit disposed on the at least one panel inorganic layer; and
an encapsulation unit disposed on the light emitting unit,
wherein the non-display region includes a notch non-display region disposed around the notch portion, and
wherein the encapsulation unit is disposed up to an end portion of the notch non-display region.

2. The display device of claim 1,
wherein the non-display region further includes an extending non-display region extending from the notch non-display region, and
wherein the printed circuit film is provided in plural number and at least one printed circuit film is attached on the extending non-display region.

3. The display device of claim 1,
wherein the notch non-display region includes a pad region to which the printed circuit film is attached.

4. The display device of claim 3,
wherein the encapsulation unit includes a first inorganic encapsulation layer on the at least one panel inorganic layer, an organic encapsulation layer on the first inorganic encapsulation layer, and a second inorganic encapsulation layer on the organic encapsulation layer, and
wherein each of the first inorganic encapsulation layer and the second inorganic encapsulation layer extends up to the end portion of the notch non-display region.

5. The display device of claim 4,
wherein the first inorganic encapsulation layer and the second inorganic encapsulation layer are not disposed in the pad region.

6. The display device of claim 4, further comprising:
a low potential voltage line, a high potential voltage line, and a data line electrically connected to the pad region,
wherein in the non-display region below the display region, the high potential voltage line is disposed between the low potential voltage line and the display region.

7. The display device of claim 6,
wherein the low potential voltage line surrounds the display region.

8. The display device of claim 7,
wherein the non-display region on a left side or a right side of the display region further includes a gate driver disposed between the low potential voltage line and the display region.

9. The display device of claim 7, further comprising:
a pixel gate driver disposed in the display region; and
a gate control line electrically connecting the pad region and the pixel gate driver to each other.

10. The display device of claim 9,
wherein the gate control line is disposed between the low potential voltage line and the display region.

11. The display device of claim 6, further comprising:
a dam portion disposed in the non-display region and overlapping the low potential voltage line,
wherein the organic encapsulation layer terminates on an inside of the dam portion.

12. The display device of claim 11, further comprising:
an anti-crack pattern disposed between an end of the display panel and the dam portion,
wherein the anti-crack pattern penetrates the at least one panel inorganic layer.

13. A display device, comprising:
a substrate including a display region having a plurality of sub-pixels and a non-display region around the display region;
at least one panel inorganic layer disposed on the substrate;
a light emitting unit disposed on the at least one panel inorganic layer;
an encapsulation unit disposed on the light emitting unit;
a display panel including a touch unit disposed on the encapsulation unit; and
a microlens disposed on a light emitting region of the sub-pixels,
wherein the encapsulation unit extends up to an end portion of the non-display region.

14. The display device of claim 13,
wherein a center of the microlens and a center of the light emitting region are mis-aligned.

15. The display device of claim 14,
wherein the plurality of sub-pixels include:
a first pixel group in which the center of the microlens is mis-aligned toward another side in a first direction with respect to the center of the light emitting region; and
a second pixel group in which the center of the microlens is mis-aligned toward one side in the first direction with respect to the center of the light emitting region.

16. The display device of claim 15,
wherein each of the first pixel group and the second pixel group extends along the first direction, and
wherein the first pixel group and the second pixel group are spaced apart in a second direction intersecting the first direction.

17. The display device of claim 14,
wherein the light emitting unit further includes an anode electrode disposed on the at least one panel inorganic layer, and
wherein the anode electrode is tilted toward the microlens.

18. The display device of claim 13,
wherein the substrate includes a notch portion,
wherein the non-display region includes a notch non-display region disposed around the notch portion, and
wherein the encapsulation unit is disposed up to an end portion of the notch non-display region.

19. The display device of claim 18, further comprising:
a plurality of printed circuit films,
wherein the non-display region further includes an extending non-display region extending from the notch non-display region, and
wherein at least one of the plurality of printed circuit films is attached on the extending non-display region.

20. The display device of claim 19,
wherein the non-display region includes a pad region to which one of the plurality of printed circuit films is attached,
wherein the encapsulation unit includes a first inorganic encapsulation layer on the at least one panel inorganic layer, an organic encapsulation layer on the first inorganic encapsulation layer, and a second inorganic encapsulation layer on the organic encapsulation layer,
wherein each of the first inorganic encapsulation layer and the second inorganic encapsulation layer extends up to the end portion of the notch non-display region, and
wherein the first inorganic encapsulation layer and the second inorganic encapsulation layer are not disposed in the pad region.
